(19) United States
(12) Patent Application Publication
(10) Pub. No.: US 2011/0261614 A1
(43) Pub. Date: Oct. 27, 2011

(54) Semiconductor device

(75) Inventor: Shuichi Tsukada, Tokyo (JP)

(73) Assignee: ELPIDA MEMORY, INC., Tokyo (JP)

(21) Appl. No.: 13/064,717

(22) Filed: Apr. 11, 2011

(30) Foreign Application Priority Data
Apr. 26, 2010 (JP) 2010-100732

(51) Int. Cl. G11C 11/00; G11C 7/00; G11C 7/10

(52) U.S. Cl. 365/163; 365/189.05; 365/191; 365/148

(57) ABSTRACT

A semiconductor device that needs a relatively long time to control a write operation and the like is reduced in size. The semiconductor device includes: first and second bit line control circuits which are arranged to correspond to first and second memory cell arrays, respectively; a control signal line that is connected to the first and second bit line control circuits in common and transmits a first control signal; and control signal lines that are connected to the first and second bit line control circuits, respectively, and transmit second and third control signals, respectively. The first bit line control circuit performs an operation control on the first memory cell array when the first and second control signals are activated. The second bit line control circuit performs an operation control on the second memory cell array when the first and third control signals are activated.

### BACKGROUND OF THE INVENTION

1. Field of the Invention

The present invention relates to a semiconductor device, and more particularly to a semiconductor device that has a plurality of memory cell arrays and needs a relatively long time to control a write operation and the like on each memory cell array.

2. Description of Related Art

Phase change random access memory (PRAM) has received attention as a nonvolatile memory in recent years. PRAM stores data by using the phase state of phase change material that is included in the recording layer. More specifically, phase change material varies greatly in electrical resistance between when in a crystalline phase and when in an amorphous phase. The difference can be used for data recording.

The phase state is changed by passing a write current through the phase change material and thereby heating the phase change material. Data is read by passing a read current through the phase change material and judging the resistance. The read current is set to a value sufficiently smaller than the write current so as not to produce a phase change. Since the phase state of the phase change material will not vary without the application of high heat, no data will be lost even after power-off.

To make phase change material amorphous (reset), the phase change material needs to be heated to its melting point or higher temperatures by the application of a reset pulse, followed by rapid cooling. To crystallize (set) phase change material, the phase change material needs to be heated to a temperature of or above its crystallization temperature and below its melting point by the application of a set pulse, followed by gradual cooling. PRAM thus has the characteristic that a longer time is needed for a set operation than for a reset operation.

In PRAM, the time needed for a set operation is thus greatly different from for a reset operation. This complicates controlling during data write, making it not easy to ensure compatibility with other general-purpose memories such as DRAM. As a solution to this problem, Japanese Patent Application Laid-Open No. 2008-112547 describes a method of supplying a plurality of timing signals (TS) having respective different phases and a plurality of timing select signals (SEL) for selecting the timing signals to write control circuits (WC) that are arranged for respective bit lines, thereby activating a plurality of write control circuits at different timing for parallel operation.

Like the PRAM described in Japanese Patent Application Laid-Open No. 2008-112547, when a plurality of write control circuits are operated in parallel, the number of write control circuits that can be operated at a time depends on the time needed for a series of write operations and the cycle of issuing commands. More specifically, assuming that the time needed for a series of write operations is A and the command issuing cycle is B, the maximum number of write control circuits capable of parallel operations is given by A/B. If the clock signal is accelerated to reduce the command issuing cycle, the maximum number of write control circuits capable of parallel operations increases. According to the method of Japanese Patent Application Laid-Open No. 2008-112547, the numbers of timing signals (TS) and timing select signals (SEL) need to be increased accordingly. This makes greater the bus area for transmitting the timing signals (TS) and the timing select signals (SEL), possibly causing an increase in chip area depending on the layout.

The foregoing problem is not limited to PRAM alone but can occur commonly in semiconductor devices of a type where the time needed for a series of write operations (A) is longer than the command issuing cycle (B). The foregoing problem is not limited to so-called semiconductor memories such as PRAM, either, but also occurs in semiconductor devices in general that partly contain PRAM cells or the like.

### SUMMARY

In one embodiment, there is provided a semiconductor device that includes: first and second memory cell arrays each having a plurality of memory cells; first and second control circuits that are arranged to correspond to the first and second memory cell arrays, respectively; a first control signal line that is connected to the first and second control circuits in common and transmits a first control signal; and second and third control signal lines that are connected to the first and second control circuits, respectively, and transmit second and third control signals, respectively, the first control circuit performing an operation control on the first memory cell array when the first and second control signals are activated, the second control circuit performing an operation control on the second memory cell array when the first and third control signals are activated, time between when the first control circuit starts the operation control on the first memory cell array and when the first control circuit ends the operation control being longer than an activation period of the first and second control signals, time between when the second control circuit starts the operation control on the second memory cell array and when the second control circuit ends the operation control being longer than an activation period of the first and third control signals.

In another embodiment, there is provided a semiconductor device that includes: a plurality of memory cell arrays that are arranged in a matrix in a row direction and a column direction, and have a plurality of memory cells each; a plurality of control circuits that are arranged to correspond to the respective plurality of memory cell arrays and each include a data latch circuit for latching write data or read data; a plurality of first control signal lines that extend in the row direction and parallel to each other in the column direction; a plurality of second control signal lines that extend in the column direction and parallel to each other in the row direction; a plurality of global I/O lines that extend in the column direction and parallel to each other in the row direction; a first control signal generating circuit that activates any one of the plurality of first control signal lines; and a second control signal generating circuit that activates any one of the plurality of second control signal lines, among the plurality of control circuits, a plurality of control circuits that belong to the same row being commonly connected to a corresponding one of the plurality of first control signal lines, among the plurality of control circuits, a plurality of control circuits that belong to the same column being commonly connected to a corresponding one of the plurality of second control signal lines, among the plurality of control circuits, a plurality of control circuits that belong to the same column being commonly connected to a corresponding one of the plurality of global I/O lines, among the plurality of control circuits, a control circuit that is connected to activated first and second control signal lines taking write data supplied through a corresponding global I/O line into the data latch circuit or supplying read data taken into the data latch circuit to the corresponding global I/O line, the plurality of memory cell arrays each including a plurality of bit lines that are connected to respective corresponding memory cells, the data latch circuits each being commonly assigned to the corresponding plurality of bit lines, the plurality of control circuits each including a bit line select circuit that supplies the write data latched in the data latch circuit to any one of the plurality of bit lines included in the corresponding memory cell array, or supplies read data read from any one of the plurality of bit lines included in the corresponding memory cell array to the data latch circuit.

In still another embodiment, there is provided a semiconductor device that includes: a memory cell array that includes a plurality of memory cells and a plurality of bit lines connected to respective corresponding memory cells; a bit line select circuit that connects anyone of the plurality of bit lines to a global bit line; a reset write driver and a set write driver that are connected to the global bit line; a data latch circuit that latches write data supplied through a global I/O line; a reset write timing latch circuit that defines an activation period of the reset write driver; and a set write timing latch circuit that defines an activation period of the set write driver, the data latch circuit latching the write data supplied through the global I/O line in response to simultaneous activation of first and second control signals, the reset write timing latch circuit entering an active state in response to simultaneous activation of first and second write start signals and entering an inactive state in response to simultaneous activation of first and second write end signals, the set write timing latch circuit entering an active state in response to the simultaneous activation of the first and second write start signals and entering an inactive state in response to simultaneous activation of third and fourth write end signals, the reset write driver supplying a reset pulse to the global bit line in response to the reset write timing latch circuit entering the active state if a first logical level is latched in the data latch circuit, the set write driver supplying a set pulse to the global bit line in response to the set write timing latch circuit entering the active state if a second logical level is latched in the data latch circuit.

In yet another embodiment, there is provided a semiconductor device that includes a write timing latch circuit that activates a write timing pulse to a potential of a first power supply line in response to an activation of a write start signal and inactivates the write timing pulse to a potential of a second power supply line in response to an activation of a write end signal; a write driver that supplies a write pulse to a bit line in response to an activation of the write timing pulse; and a memory cell connected to the bit line, wherein the memory cell includes a nonvolatile memory element using phase change material, the write timing latch circuit includes: a flip-flop circuit connected between the first and second power supply lines, the flip-flop circuit having first and second input nodes; a first transistor connected between the first input node and the second power supply line, the first transistor having a control electrode supplied with the write start signal; a second transistor connected between the second input node and the second power supply line, the first transistor having a control electrode supplied with the write end signal; a third transistor connected between the first transistor and the first input node; and a fourth transistor connected between the second transistor and the second input node, the first to fourth transistors are MOS transistors, gates of the third and fourth transistors are connected to a third power supply line to which an potential between the potential of the first power supply line and that of the second power supply line is supplied, and the first to fourth transistors have a gate insulating film thinner than that of MOS transistors that constitute the flip-flop circuit.

According to the present invention, predetermined control circuits are selectively activated by using the control signals, instead of supplying timing signals or the like to all the control circuits in common. It is therefore possible to reduce the number of wiring lines that transmit timing signals etc. In addition, the control circuits are simplified in circuit configuration with a reduction in the occupying area. This makes it possible to reduce the chip area.

According to the present invention, the MOS transistors for controlling the flip-flop circuits need not be a high-voltage transistor. This makes it possible to reduce the size of the control circuits of the memory cells that include the nonvolatile memory elements made of phase change material while suppressing the off-leak currents. Since the gate capacitances are also reduced, it is even possible to reduce the operating power consumption.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a general view of a semiconductor device 10 according to a preferred embodiment of the present invention;

FIG. 2 is a diagram showing a configuration of a first bank BANK_A in detail;

FIG. 3 is a circuit diagram of a memory cell;

FIGS. 4A to 4C are graphs showing operation waveforms in a write operation, where FIG. 4A shows a waveform of current that flows a phase change element PC, FIG. 4B shows a waveform of a voltage that is applied to the phase change element PC, and FIG. 4C shows a temperature waveform of the phase change element PC;

FIG. 5 is an example of a circuit diagram of a phase timing circuit PTC, where circuit components related to write operation control are extracted in particular;

FIG. 6 is an example of a circuit diagram of a control signal generating circuit 14X, where circuit sections related to write operation control are detailed in particular;

FIG. 7 is a circuit diagram of bit line control circuits BLC;

FIG. 8 is a circuit diagram of a data switch control unit BLCSW;

FIG. 9 is a circuit diagram of a write control unit BLCW;

FIG. 10 is a timing chart for mainly explaining an operation of a column control circuit CC when column commands are issued;

FIG. 11 is a timing chart for mainly explaining an operation of the bit line control circuits BLC when column commands are issued;

FIG. 12 is a circuit diagram of the write control unit BLCW according to a modification;

FIGS. 13A and 13B are graphs showing a relationship between a gate-source voltage and a drain current, where FIG. 13A is a graph showing the drain current on a log scale, and FIG. 13B is a graph showing the drain current on a normal scale; and

FIG. 14 is a timing chart when a method of reading read data from a memory cell MC in response to a read command is used.

### DETAILED DESCRIPTION OF THE EMBODIMENTS

Preferred embodiments of the present invention will be explained below in detail with reference to the accompanying drawings.

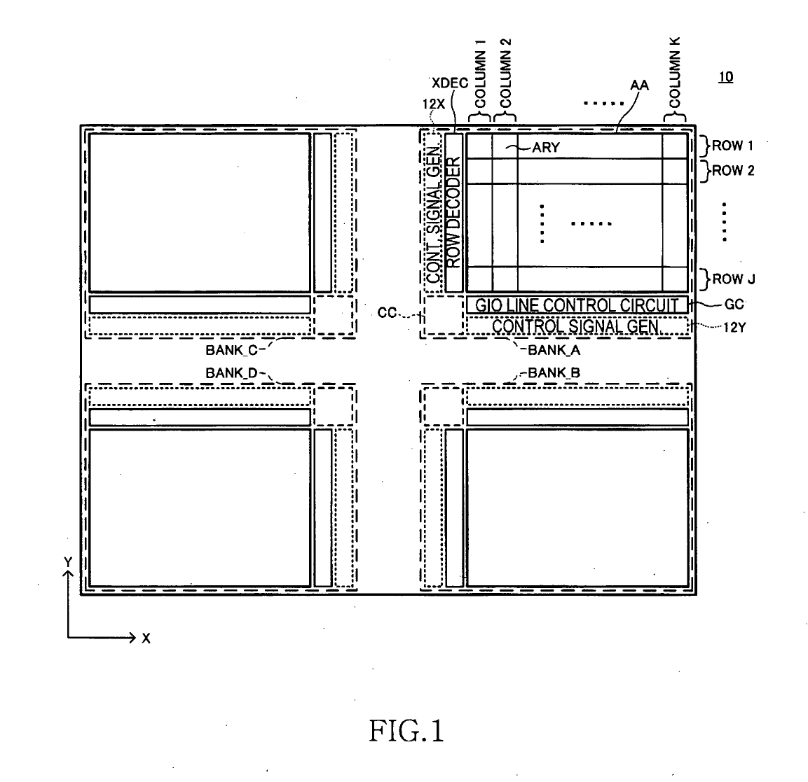

FIG. 1 is a general view of a semiconductor device 10 according to a preferred embodiment of the present invention. The semiconductor device 10 according to the present embodiment is a PRAM which is integrated into a single chip.

As shown in FIG. 1, the semiconductor device 10 according to the present embodiment includes four banks BANK_A to BANK_D. The banks are units that can separately accept commands. The plurality of banks can thus make parallel operations. Since the banks have the same circuit configuration, the circuit configuration will hereinafter be described with the first bank BANK_A as an example.

The first bank BANK_A has an array area AA which includes a plurality of memory cell arrays ARY. The plurality of memory cell arrays ARY included in the array area AA are laid out in a matrix in the X direction (row direction) and Y direction (column direction). FIG. 1 shows an example of a matrix arrangement with J rows×K columns.

As shown in FIG. 1, a control signal generating circuit area 12X and a row decoder XDEC are arranged on one side of the array area AA in the X direction. A control signal generating circuit area 12Y and a GIO line control circuit GC are arranged on one side of the array area AA in the Y direction. A column control circuit CC is arranged in an area where an extension of the control signal generating circuit area 12X and the row decoder XDEC in the Y direction and an extension of the control signal generating circuit area 12Y and the GIO line control circuit GC in the X direction intersect each other, i.e., in a position diagonal to the array area AA.

Specific configurations of the circuits will be described below.

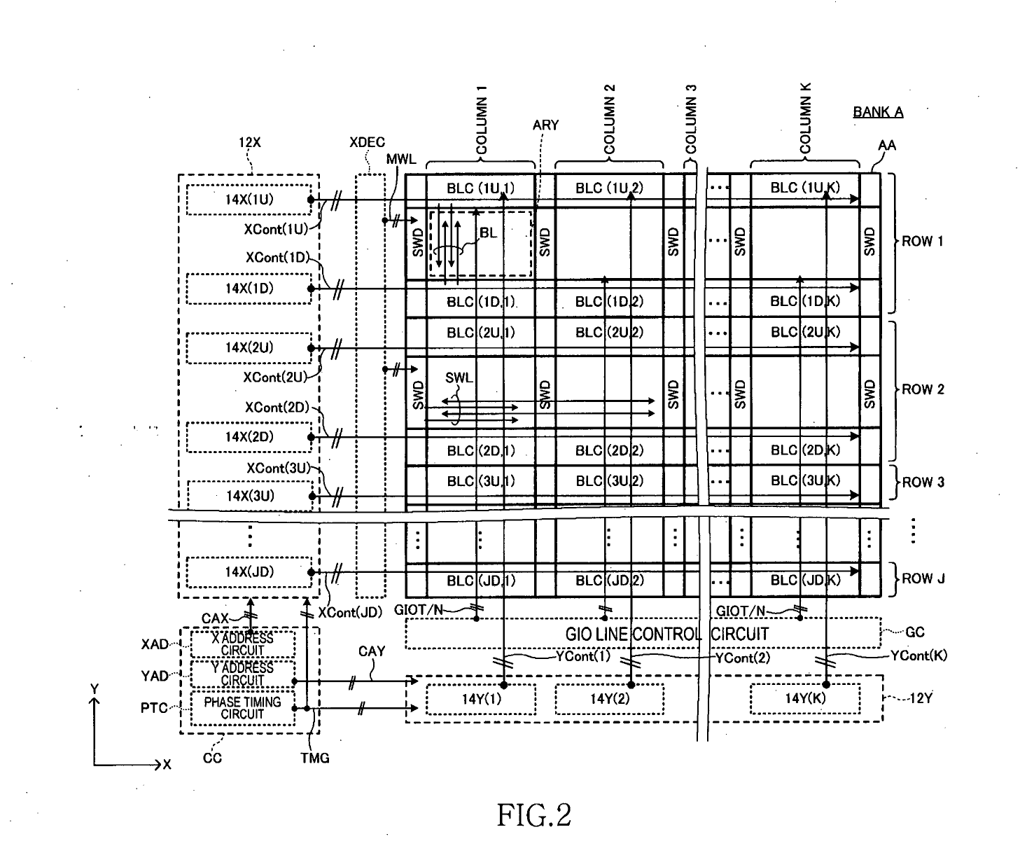

FIG. 2 is a diagram showing the configuration of the first bank BANK_A in more detail.

As shown in FIG. 2, sub word drivers SWD are arranged on both sides of each memory cell array ARY in the X direction. The sub word drivers SWD are circuits for driving sub word lines SWL that are arranged in the corresponding memory cell arrays ARY. The sub word drivers SWD perform their control based on a row address. More specifically, part of a row address supplied to the row decoder XDEC is pre-decoded to select any one of main word lines MWL, and the rest of the row address is pre-decoded into a signal which is supplied to the sub word drivers SWD. Consequently, any one of the sub word lines SWL that is specified by the row address is selected. The sub word lines SWL are wiring that extends in the X direction in the memory cell arrays ARY. Adjoining sub word lines SWL are driven by the sub word drivers SWD on opposite sides, respectively.

Bit line control circuits BLC are arranged on both sides of each memory cell array ARY in the Y direction. The bit line control circuits BLC are circuits for performing a write operation and a read operation through bit lines BL that are arranged in the corresponding memory cell array ARY. The bit line control circuits BLC perform their control based on control signals XCont and YCont which are supplied from the control signal generating circuit areas 12X and 12Y and, in a write operation, write data which is supplied through global I/O lines GIO. The bit lines BL are wiring that extends in the Y direction within the memory cell arrays ARY. Adjoining bit lines BL are connected to the bit line control circuits BLC on opposite sides, respectively.

In other words, half of the plurality of memory cells included in a memory cell array ARY (for example, memory cells that are connected to odd-numbered bit lines BL) are controlled by the bit line control circuit BLC that is shown on the upper side in FIG. 2. The remaining half of the memory cells (for example, memory cells that are connected to even-numbered bit lines BL) are controlled by the bit line control circuit BLC that is shown on the lower side in FIG. 2. Here, the bit line control circuit BLC arranged on the upper side of the memory cell array ARY will be referred to as a “U-side (Up side)” bit line control circuit. The bit line control circuit BLC arranged on the lower side of the memory cell array ARY will be referred to as a “D-side (Down side)” bit line control circuit. In FIG. 2, the parenthesized symbols that follow the symbol BLC represent the row number of that bit line control circuit BLC, the distinction between the U-side and D-side, and the column number of the bit line control circuit BLC. For example, the bit line control circuit denoted as BLC(1U,1) represents the U-side bit line control circuit that is assigned to the memory cell array ARY belonging to the first row and first column. The circuit configuration of the bit line control circuits BLC will be described later.

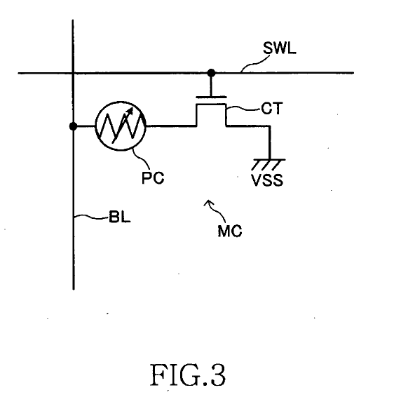

FIG. 3 is a circuit diagram of a memory cell.

As shown in FIG. 3, the memory cell MC includes a phase change element PC and a cell transistor CT which are connected in series between a corresponding bit line BL and a VSS power supply line (ground wiring). The cell transistor CT is an N-channel MOS transistor. The gate electrode of the cell transistor CT is connected to a corresponding sub word line SWL. The phase change element PC is formed to include a phase change material. The phase change material is not limited to any particular one as long as the material has two or more phase states and varies in electrical resistance depending on the phase state. So-called chalcogenide material is preferably selected. Chalcogenide material refers to an alloy that can selectively take either an amorphous phase with a relatively high resistance or a crystalline phase with a relatively low resistance, and contains at least one or more of germanium (Ge), antimony (Sb), tellurium (Te), indium (In), and selenium (Se). Examples include binary alloys such as GaSb, InSb, InSe, Sb₂Te₃, and GeTe, ternary alloys such as Ge₂Sb₂Te₅, InSbTe, GaSeTe, SnSb₂Te₄, and InSbGe, and quarternary alloys such as AgInSbTe, (GeSn)SbTe, GeSb(SeTe), and Te₈₁Ge₁₅Sb₂S₂.

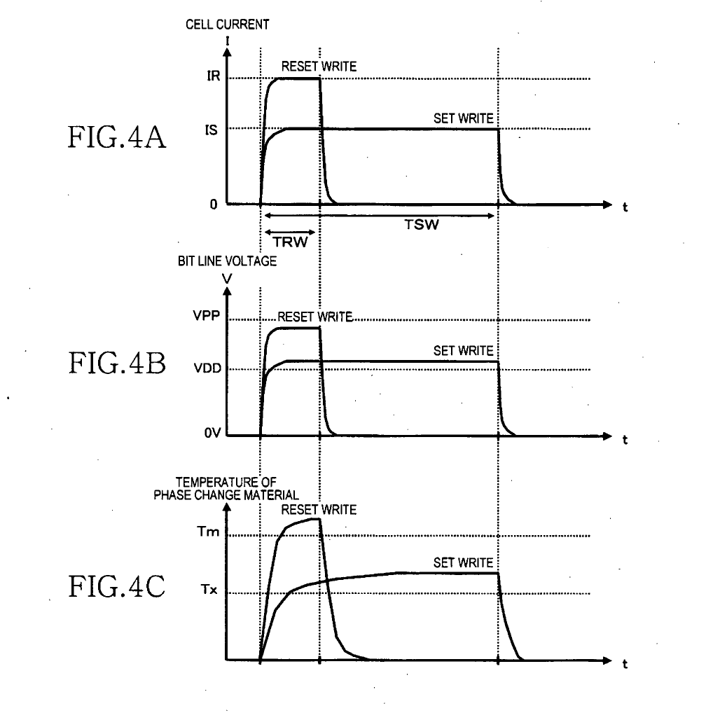

FIGS. 4A to 4C are graphs showing operation waveforms in a write operation. FIG. 4A shows the waveform of the current that flows the phase change element PC. FIG. 4B shows the waveform of the voltage that is applied to the phase change element PC. FIG. 4C shows the temperature waveform of the phase change element PC.

There are two types of write operations, a “reset write” and a “set write.” The reset write refers to a write operation for making the phase change material amorphous. The amorphous phase change element PC has a relatively high resistance, which corresponds, for example, to a state where a logical value “0” is stored. In contrast, the set write refers to a write operation for crystallizing the phase change material. The crystallized phase change element PC has a relatively low resistance, which corresponds, for example, to a state where a logical value “1” is stored.

To perform a reset write, as shown in FIGS. 4A and 4B, the current (cell current) to flow the phase change element PC is set to IR, and the voltage (bit line voltage) applied to the phase change element PC is set to near VPP. The duration of application is a reset write period TRW. Consequently, as shown in FIG. 4C, the temperature of the phase change element PC exceeds the melting point Tm of the phase change material. When the reset write period TRW ends to stop the application of the current and voltage, the phase change element PC is rapidly cooled so that the phase change material becomes amorphous.

To perform a set write, as shown in FIGS. 4A and 4B, the current (cell current) to flow the phase change element PC is set to IS (<IR), and the voltage (bit line voltage) applied to the phase change element PC is set to near VDD (<VPP). The duration of application is a set write period TSW which is longer than the reset write period TRW. Consequently, as shown in FIG. 4C, the phase change element PC is heated to a temperature of or above the crystallization temperature Tx and below the melting point Tm of the phase change material. Such a state is maintained for the set write period TSW, whereby the phase change material is crystallized.

Returning to FIG. 2, a plurality of control signal generating circuits 14X are arranged in the control signal generating circuit area 12X. Each of the control signal generating circuits 14X is a circuit for supplying control signals XCont to the plurality of bit line control circuits BLC that are arranged in the corresponding row. In FIG. 2, the parenthesized symbols that follow the symbol 14X represent the row number of the corresponding bit line control circuits BLC and the distinction between the U-side and D-side. For example, the control signal generating circuit denoted as 14X(1U) represents the control signal generating circuit corresponding to the U-side bit line control circuits that are assigned to the first row of memory cell arrays ARY. The control signal generating circuit 14X(1U) then supplies the same control signals XCont to K bit line control circuits BLC(1U, 1 to K) by using common wiring extending in the X direction. The circuit configuration of the control signal generating circuits 14X will be described later.

Similarly, a plurality of control signal generating circuits 14Y are arranged in the control signal generating circuit area 12Y. Each of the control signal generating circuits 14Y is a circuit for supplying control signals YCont to the plurality of bit line control circuits BLC that are arranged in the corresponding column. In FIG. 2, the parenthesized symbol that follows the symbol 14Y represents the column number of the corresponding bit line control circuits BLC. For example, the control signal generating circuit denoted as 14Y(1) represents the control signal generating circuit corresponding to the bit line control circuits that are assigned to the first column of memory cell arrays ARY. The control signal generating circuit 14Y(1) then supplies the same control signals YCont to 2J bit line control circuits BLC(1U to JU,1) and BLC(1D to JD,1) by using common wiring extending in the Y direction. The control signal generating circuits 14Y have the same circuit configuration as that of the control signal generation circuits 14X which will be described later.

A plurality of pairs of global I/O lines GIO are commonly connected to the 2J bit line control circuits BLC that belong to the same column. The global I/O lines GIO are complementary wiring for transmitting write data and read data, and are connected to the bit lines BL through global bit lines to be described later. The global I/O lines GIO are wiring extending in the Y direction.

As shown in FIG. 2, the column control circuit CC includes an X address circuit XAD, a Y address circuit YAD, and a phase timing circuit PTC. The X address circuit XAD is a circuit that supplies an X column address CAX to the control signal generating circuits 14X. The Y address circuit YAD is a circuit that supplies a Y column address CAY to the control signal generating circuits 14Y. The phase timing circuit PTC is a circuit that supplies timing signals TMG to the control signal generating circuits 14X and 14Y. Incidentally, timing signals TMG output from the same buffer may be supplied to the control signal generating circuits 14X and 14Y in common. Timing signals TMG output from different buffers may be supplied to the respective control signal generating circuits 14X and 14Y.

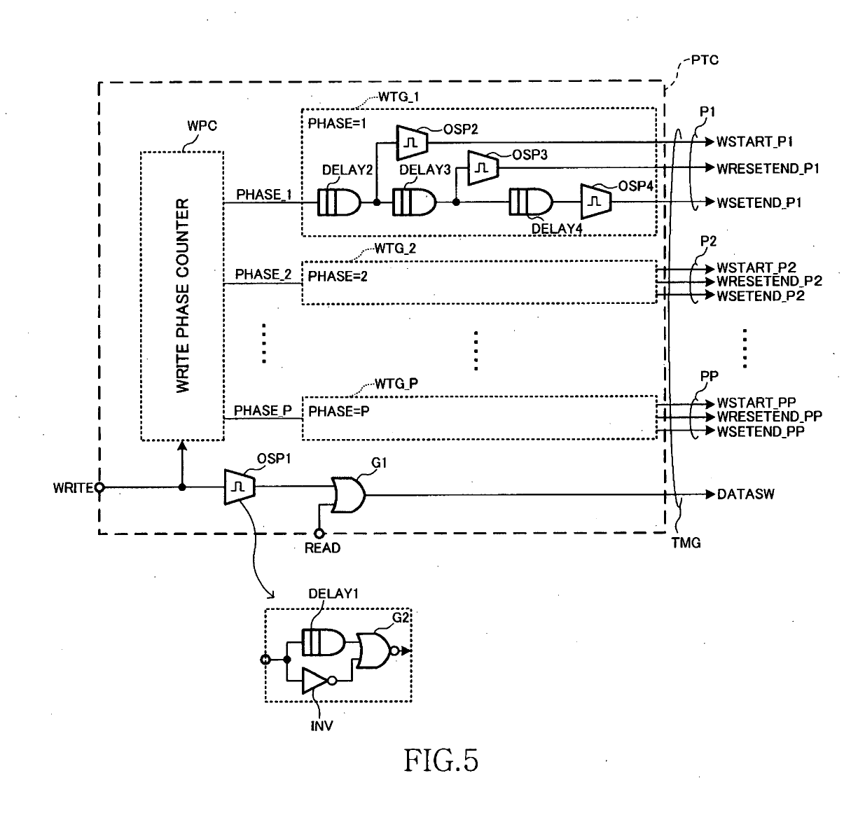

FIG. 5 is an example of a circuit diagram of the phase timing circuit PTC, where circuit components related to write operation control are extracted in particular.

As shown in FIG. 5, the timing signals TMG generated by the phase timing circuit. PTC includes P groups of signals consisting of a group of phase-1 signals P1 to a group of phase-P signals PP, and a data switch signal DATASW. The group of phase-1 signals P1 to the group of phase-P signals PP are groups of signals having respective different phases. The number of such groups of signals, i.e., the number P of write phases can be set to an appropriate number based on the relationship between the write characteristics of the memory cells and the specification of the array operation cycle. Specifically, the number P of write phases may be determined depending on how many cycles of the interval of issuance TCCD of column commands (write commands or read commands) the set write period TSW shown in FIG. 4 lasts for. That is, the setting may be as follows:

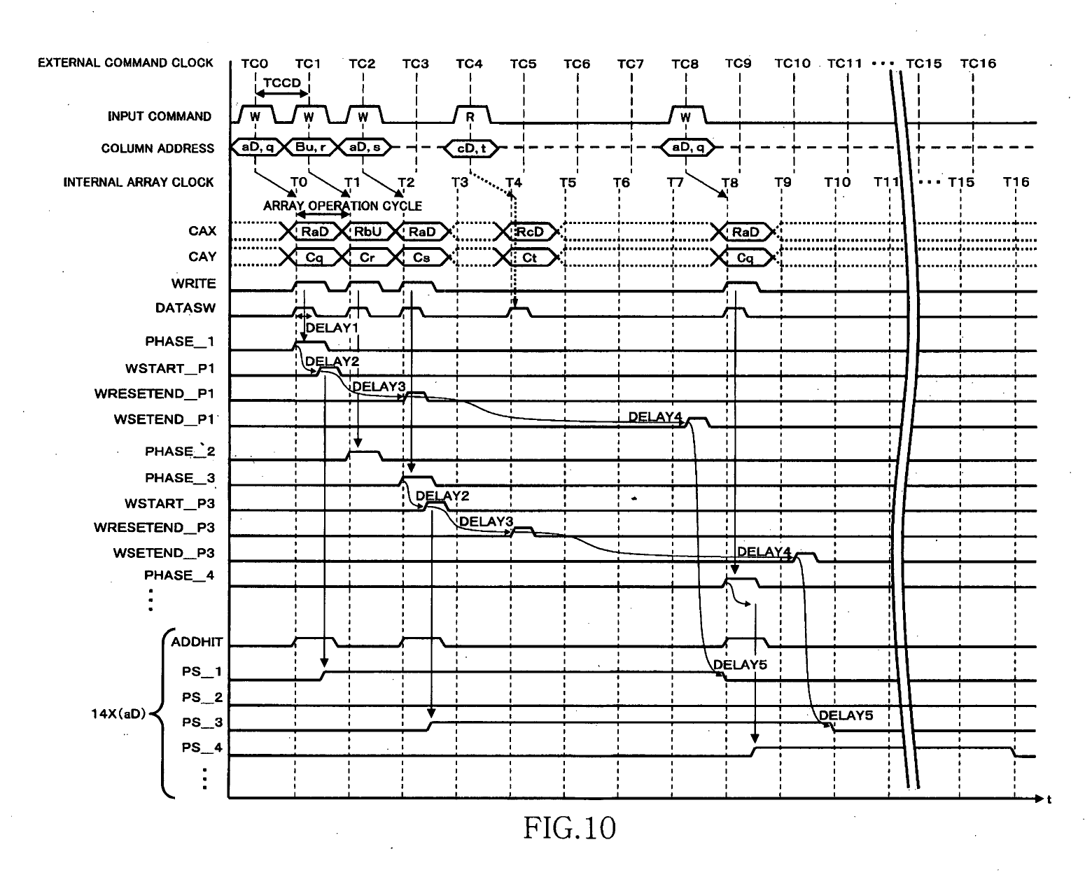

The number P of write phases>TSW/TCCD. As shown in FIG. 10 to be seen later, the array operation cycle has the same duration as the interval of issuance TCCD of the column commands.

The group of phase-1 signals P1 to the group of phase-P signals PP include write start signals WSTART_P1 to WSTART_PP, and write end signals WRESETEND_P1 to WRESETEND_PP and WSETEND_P1 to WSETEND_PP, respectively. The write start signals WSTART_P1 to WSTART_PP are signals that define the start timing of a set write and a reset write, and correspond to phase 1 to phase P, respectively. The write end signals WRESETEND_P1 to WRESETEND_PP are signals that define the end timing of a reset write, and correspond to phase 1 to phase P, respectively. The write end signals WSETEND_P1 to WSETEND_PP are signals that define the end timing of a set write, and correspond to phase 1 to phase P, respectively.

The group of phase-1 signals P1 to the group of phase-P signals PP are generated by respective corresponding write timing generators WTG_1 to WTG_P. The write timing generators WTG_1 to WTG_P are activated by phase signals PHASE_1 to PHASE_P which are generated by a write phase counter WPC. The write phase counter WPC counts up or counts down each time a write instruction signal WRITE is activated. Based on the count value, the write phase counter WPC activates any one of the phase signals PHASE_1 to PHASE_P to a high level. The write instruction signal WRITE is an internal command that is activated when a write command is issued from outside.

As shown in FIG. 5, the write timing generator WTG_1 includes delay circuits DELAY2 to DELAY4 which delay the phase signal PHASE_1, and one-shot pulse generating circuits OSP2 to OSP4 which generate a one-shot pulse when the outputs of the delay circuits DELAY2 to DELAY4 change from a low level to high level, respectively. The outputs of the one-shot pulse generating circuits OSP2 to OSP4 are used as the write start signal WSTART_P1, the write end signal WRESETEND_P1, and the write end signal WSETEND_P1, respectively. As shown in FIG. 5, since the delay circuits DELAY2 to DELAY4 are connected in series in this order, the activation of the phase signal PHASE_1 to a high level activates the write start signal WSTART_P1, the write end signal WRESETEND_P1, and the write end signal WSETEND_P1 in this order. Consequently, the amount of delay of the delay circuit DELAY3 defines the reset write period TRW. The sum of the amounts of delay of the delay circuits DELAY3 and DELAY4 defines the set write period TSW.

The other write timing generators WTG_2 to WTG_P have the same circuit configuration as that of the write timing generator WTG_1.

The write instruction signal WRITE is supplied to an OR gate circuit G1 through a one-shot pulse generating circuit OSP1. A read instruction signal READ is also supplied to the OR gate circuit G1. The read instruction signal READ is an internal command that is activated when a read command is issued from outside. Consequently, when a write command or read command is issued from outside, there occurs a one-shot data switch signal DATASW.

Each of the one-shot pulse generating circuits OSP1 to OSP4 includes a delay circuit DELAY1, an inverter INV, and a NOR gate circuit G2 which receives the outputs of the delay circuit DELAY1 and the inverter INV. The pulse width of the one-shot pulse to be generated when the input signal changes from a low level to high level is thus defined by the amount of delay of the delay circuit DELAY1. The pulse width of the one-shot pulse is designed to be shorter than the interval of issuance TCCD of column commands.

The group of phase-1 signals P1 to the group of phase-P signals PP and the data switch signal DATASW thus generated are supplied to the control signal generating circuits 14X and 14Y as mentioned above.

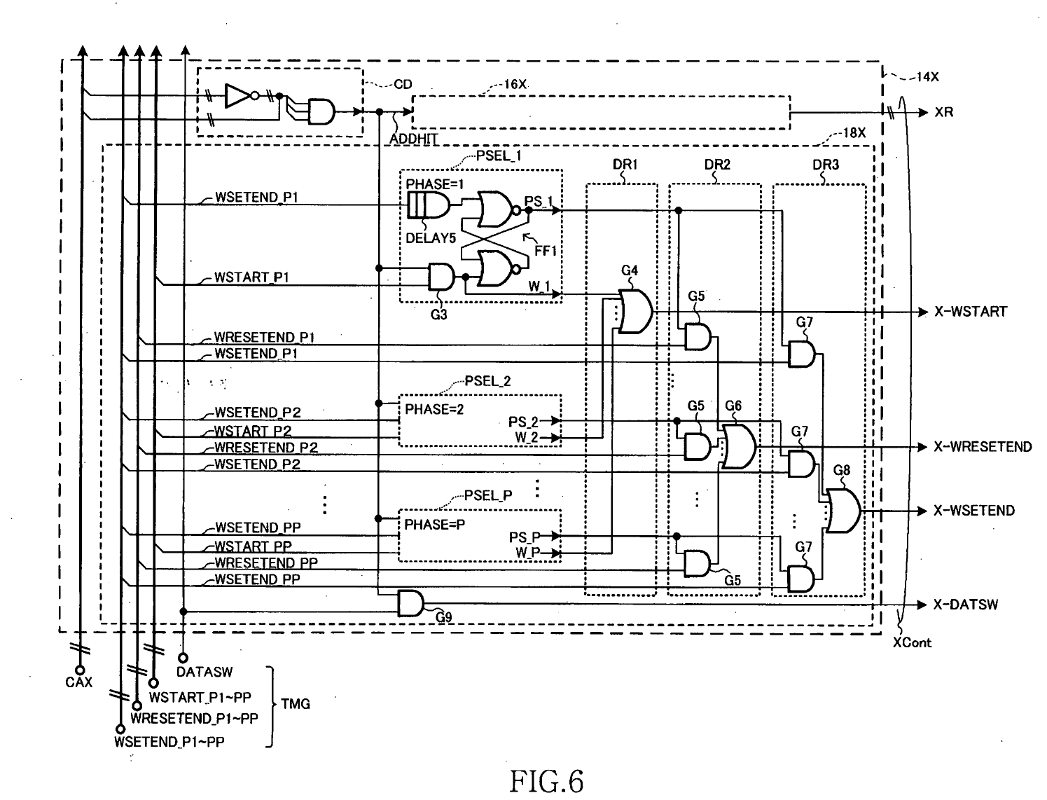

FIG. 6 is an example of a circuit diagram of a control signal generating circuit 14X, where circuit sections related to write operation control are detailed in particular.

As shown in FIG. 6, the control signal generating circuit 14X includes a column decoder circuit CD, a read timing signal generating circuit 16X, and a write timing signal generating circuit 18X. The column decoder circuit CD is a circuit that compares the X column address CAX supplied from the X address circuit XAD with a column address unique to this control signal generating circuit 14X, and activates a hit signal ADDHIT if the addresses coincide with each other. The column address set in the control signal generating circuit 14X is an address that each of the 2J control signal generating circuits 14X included in the control signal generating circuit area 12X uniquely has. When an X column address CAX is supplied, any one of the 2J control signal generating circuits 14X exclusively activates its hit signal ADDHIT. The hit signal ADDHIT is supplied to the read timing signal generating circuit 16X and the write timing signal generating circuit 18X.

The write timing signal generating circuit 18X includes P phase selectors PSEL_1 to PSEL_P, a driver circuit DR1 which generates a write start signal X-WSTART, a driver circuit DR2 which generates a write end signal X-WRESETEND, and a driver circuit DR3 which generates a write end signal X-WSETEND.

The phase selectors PSEL_1 to PSEL_P are circuits of the same circuit configuration and to be set in synchronization with the respective corresponding write start signals WSTART_P1 to WSTART_PP and reset in synchronization with the respective corresponding write end signals WSETEND_P1 to WSETEND_PP. More specifically, the phase selector PSEL_1 includes the following: an AND gate circuit G3 which receives the hit signal ADDHIT and the corresponding write start signal WSTART_P1; a delay circuit DELAY5 which delays the corresponding write end signal WSETEND_P1; and an RS latch circuit FF1 which is set by the output of the AND gate circuit G3 and reset by the output of the delay circuit DELAY5. The delay time of the delay circuit DELAYS is optimally set to be slightly longer than the pulse width of the write end signals WSETEND_P1 to WSETEND_PP, one-shot pulses. The output of the AND gate circuit G3 is used as a write signal W_1. The output of the RS flip-flop circuit FF1 is used as a phase select signal PS_1. The other phase selectors PSEL_2 to PSEL_P have the same circuit configuration.

With such a configuration, when the hit signal ADDHIT is activated to a high level, the phase whose write start signal WSTART_P1 to WSTART_PP is active at that timing is selected. The RS flip-flop circuit FF included in one of the phase selectors PSEL_1 to PSEL_P that corresponds to the phase is set. The corresponding write signals W_1 to W_P are also activated to a high level. Subsequently, when either one of the write end signals WSETEND_P1 to WSETEND_PP that corresponds to the phase is activated, the RS flip-flop circuit FF is reset to change the corresponding select signals PS_1 to PS_P to a low level.

The write signals W_1 to W_P thus generated are supplied to the driver circuit DR1. The phase select signals PS_1 to PS_P are supplied to the driver circuits DR2 and DR3.

The driver circuit DR1 is composed of a P-input OR gate circuit G4 which receives the write signals W_1 to W_P as its input signals. The output is used as the write start signal X-WSTART. Consequently, when any one of the phase selectors PSEL_1 to PSEL_P is set, the write start signal X-WSTART is activated to a high level.

The driver circuit DR2 includes AND gate circuits G5 which receive the respective corresponding phase select signals PS_1 to PS_P and the respective corresponding write end signals WRESETEND_P1 to WRESETEND_PP, and a P-input OR gate circuit G6 which receives the outputs of the AND gate circuits G5. The output of the driver circuit DR2 is used as the write end signal X-WRESETEND. Consequently, when a write end signal WRESETEND_P1 to WRESETEND_PP that corresponds to the set phase selector PSEL_1 to PSEL_P is activated, the write end signal X-WRESETEND is activated to a high level.

The driver circuit DR3 includes AND gate circuits G7 which receive the respective corresponding phase select signals PS_1 to PS_P and the respective corresponding write end signals WSETEND_P1 to WSETEND_PP, and a P-input OR gate circuit G8 which receives the outputs of the AND gate circuits G7. The output of the driver circuit DR3 is used as the write end signal X-WSETEND. Consequently, when a write end signal WSETEND_P1 to WSETEND_PP that corresponds to the set phase selector PSEL_1 to PSEL_P is activated, the write end signal X-WSETEND is activated to a high level.

The write timing signal generating circuit 18X also includes an AND gate circuit G9 which receives the hit signal ADDHIT and the data switch signal DATASW. The output of the AND gate circuit G9 is used as a data switch signal X-DATASW.

The read timing signal generating circuit 16X is a circuit that generates a read signal XR. The read signal XR is a timing signal for performing a read operation in synchronization with a read command and for generating read signals SIG1 to SIG3 to be described later. The read signal XR is transmitted through a plurality of signal lines. The read timing signal generating circuit 16X may have the same circuit configuration as that of the write timing signal generating circuit 18X described above.

The various types of signals XR, X-WSTART, X-WRESETEND, X-WSETEND, and X-DATASW thus generated are the signals that correspond to the control signals XCont shown in FIG. 2.

The circuit configuration of the control signal generating circuits 14X has been described so far. As can be seen from above, the control signal generating circuits 14X have the function of retaining the write phase when the X column address CAX hits, and activating the write end signals X-WRESETEND and X-WSETEND when the write end signals WRESETEND_P1 to WRESETEND_PP and WSETEND_P1 to WSETEND_PP corresponding to that phase are activated, respectively.

The control signal generating circuits 14Y shown in FIG. 2 have the same circuit configuration as that of the control signal generating circuit 14X shown in FIG. 6 except in that the X-system signals are replaced with Y-system ones. As shown in FIG. 2, the control signal generating circuits 14X having such a circuit configuration are provided as many as 2J, and each commonly supplies the same control signals XCont (XR, X-WSTART, X-WRESETEND, X-WSETEND, and X-DATASW) to the K bit line control circuits BLC by using the common wiring extending in the X direction. Similarly, as shown in FIG. 2, the control signal generating circuits 14Y are provided as many as K, and each commonly supplies the same control signals YCont (YR, Y-WSTART, Y-WRESETEND, Y-WSETEND, and Y-DATASW) to the 2J bit line control circuits BLC by using the common wiring extending in the Y direction.

In terms of the bit line control circuits BLC(1U,1), BLC(1U,2), BLC(2U,1) and BLC(2U,2) shown in FIG. 2, the control signal lines that transmit the control signals XCont(1U) are connected to the bit line control circuits BLC(1U,1) and BLC(1U,2) in common. The control signal lines that transmit the control signals XCont(2U) are connected to the bit line control circuits BLC(2U,1) and BLC(2U,2) in common. The control signal lines that transmit the control signals YCont(1) are connected to the bit line control circuits BLC(1U,1) and BLC(2U,1) in common. The control signal lines that transmit the control signals YCont(2) are connected to the bit line control circuits BLC(1U,2) and BLC(2U,2) in common. The signal lines for transmitting the control signals XCont are composed of the signal lines that transmit the signals XR, X-WSTART, X-WRESETEND, X-WSETEND, and X-DATASW. Similarly, the signal lines for transmitting the control signals YCont are composed of the signal lines that transmit the signals YR, Y-WSTART, Y-WRESETEND, Y-WSETEND, and Y-DATASW. For example, the wiring for transmitting the write start signals X-WSTART and Y-WSTART includes the write start signal lines. The wiring for transmitting the write end signals X-WRESETEND, Y-WRESETEND, X-WSETEND, and Y-WSETEND includes the write end signal lines. Each bit line control circuit BLC is selected when the corresponding data switch signals X-DATASW and Y-DATASW are simultaneously activated. The bit line control circuit BLC starts a write operation when the corresponding write start signals X-WSTART and Y-WSTART are simultaneously activated. The bit line control circuit BLC ends a reset write operation when the corresponding write end signal X-WRESETEND and Y-WRESETEND are simultaneously activated. The bit line control circuit BLC ends a set write operation when the corresponding write end signals X-WSETEND and Y-WSETEND are simultaneously activated.

The power supplies of the circuits that constitute the control signal generating circuits 14X and 14Y are connected to a VDD power supply line and a VSS power supply line, so that the control signals XCont and YCont generated have an amplitude of between VDD and VSS.

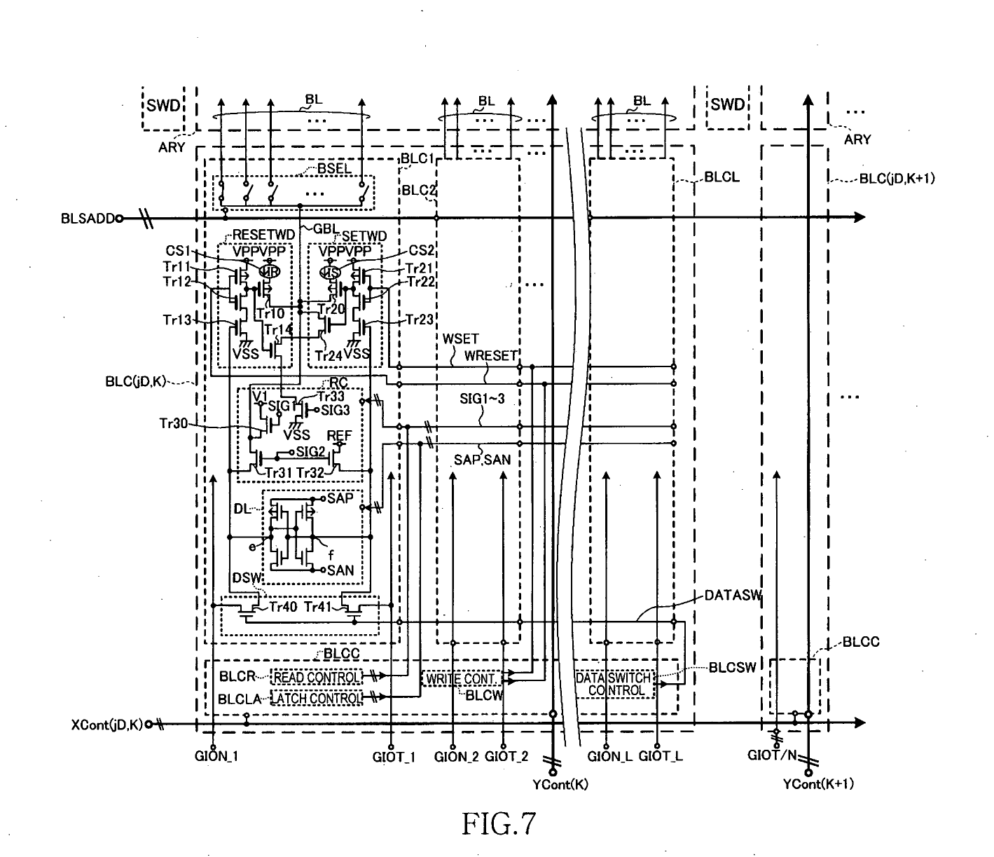

FIG. 7 is a circuit diagram of the bit line control circuits BLC. The bit line control circuit BLC(jD,k) is shown as an example.

As shown in FIG. 7, a single bit line control circuit BLC includes a plurality of bit line control unit circuits BLC1 to BLCL and a common control circuit BLCC which is provided for the bit line control unit circuits BLC1 to BLCL in common. The bit line control unit circuits BLC1 to BLCL are connected to respective different pairs of global I/O lines. For example, the bit line control unit circuit BLC1 is connected to a pair of global I/O lines GIOT_1 and GION_1. The bit line control unit circuit BLC2 is connected to a pair of global I/O lines GIOT_2 and GION_2.

The common control circuit BLCC includes a read control unit BLCR, a write control unit BLCW, a latch control unit BLCLA, and a data switch control unit BLCSW. The bit line control unit circuits BLC1 to BLCL each include a bit line select circuit BSEL, a reset write driver RESETWD, a set write driver SETWD, a read circuit RC, a data latch circuit DL, and a data switch circuit DSW. Hereinafter, the circuit blocks that constitute the bit line control circuits BLC will be described in detail.

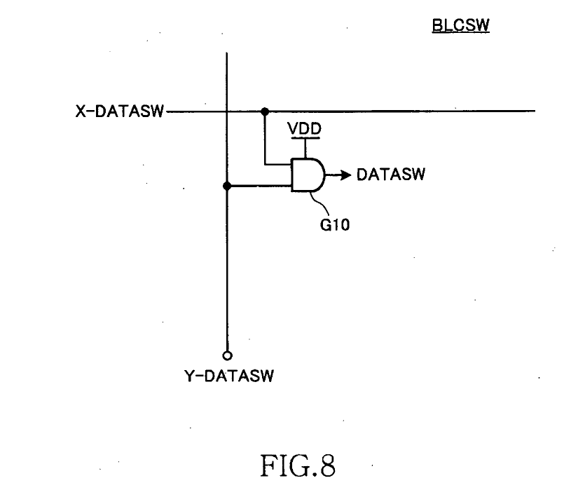

FIG. 8 is a circuit diagram of the data switch control unit BLCSW.

As shown in FIG. 8, the data switch control unit BLCSW is composed of an AND gate circuit G10 which receives the corresponding data switch signals X-DATASW and Y-DATASW. The output of the AND gate circuit G10 is used as the data switch signal DATASW, which is commonly supplied to the data switch circuits DSW included in the bit line control unit circuits BLC1 to BLCL. As mentioned previously, the data switch signal X-DATASW is commonly supplied to the K bit line control circuits BLC that belong to the same row. The data switch signal Y-DATASW is commonly supplied to the 2J bit line control circuits BLC that belong to the same column. When any one of the data switch signals X-DATASW and any one of the data switch signals Y-DATASW are activated, only one of the K×2J bit line control circuits BLC laid out in a matrix in the row and column directions is selected, and the data switch signal DATASW in the selected bit line control circuit BLC is activated to a high level.

The power supply of the AND gate circuit G10 which constitutes the data switch control unit BLCSW is connected to the VDD power supply line. This means that the data switch signal DATASW output has an amplitude of VDD.

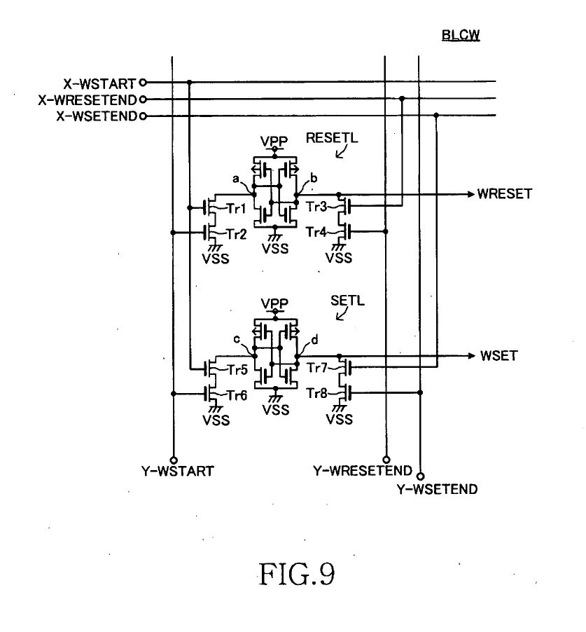

FIG. 9 is a circuit diagram of the write control unit BLCW.

As shown in FIG. 9, the write control unit BLCW includes a reset write timing latch circuit RESETL and a set write timing latch circuit SETL. The reset write timing latch circuit RESETL is a circuit that defines the reset write period TRW when in a write operation. The reset write timing latch circuit RESETL generates a reset write timing pulse WRESET. The set write timing latch circuit SETL is a circuit that defines the set write period TSW when in a write operation. The set write timing latch circuit SETL generates a set write timing pulse WSET.

The reset write timing latch circuit RESETL and the set write timing latch circuit SETL both are a flip-flop circuit having two cross-coupled inverters. The power supplies are connected to the VPP (>VDD) power supply line and VSS power supply line.

N-channel MOS transistors Tr1 and Tr2 are connected in series between one input node a of the reset write timing latch circuit RESETL and the VSS power supply line. The corresponding write start signal X-WSTART is supplied to the gate electrode of the transistor Tr1. The corresponding write start signal Y-WSTART is supplied to the gate electrode of the transistor Tr2. N-channel MOS transistors Tr3 and Tr4 are connected in series between the other input node b of the reset write timing latch circuit RESETL and the VSS power supply line. The corresponding write end signal X-WRESETEND is supplied to the gate electrode of the transistor Tr3. The corresponding write end signal Y-WRESETEND is supplied to the gate electrode of the transistor Tr4.

Similarly, N-channel MOS transistors Tr5 and Tr6 are connected in series between one input node c of the set write timing latch circuit SETL and the VSS power supply line. The corresponding write start signal X-WSTART is supplied to the gate electrode of the transistor Tr5. The corresponding write start signal Y-WSTART is supplied to the gate electrode of the transistor Tr6. N-channel MOS transistors Tr7 and Tr8 are connected in series between the other input node d of the set write timing latch circuit SETL and the VSS power supply line. The corresponding write end signal X-WSETEND is supplied to the gate electrode of the transistor Tr7. The corresponding write end signal Y-WSETEND is supplied to the gate electrode of the transistor Tr8.

With the foregoing configuration, when the corresponding write start signals X-WSTART and Y-WSTART are activated to a high level, the reset write timing latch circuit RESETL and the set write timing latch circuit SETL both enter an active state. The reset write timing pulse WRESET and the set write timing pulse WSET, the outputs of the circuits, are both activated to a high level. Subsequently, when the corresponding write end signals X-WRESETEND and Y-WRESETEND are activated to a high level, the reset write timing latch circuit RESETL enters an inactive state. The reset write timing pulse WRESET, the output of the reset write timing latch circuit RESETL, is deactivated to a low level. Subsequently, when the corresponding write end signals X-WSETEND and Y-WSETEND are activated to a high level, the set write timing latch circuit SETL enters an inactive state. The set write timing pulse WSET, the output of the set write timing latch circuit SETL, is deactivated to a low level.

In FIG. 9, the gate electrodes of all the MOS transistors are shown in thick lines, which means that the transistors are high-voltage transistors having a gate insulator thicker than that of normal VDD-powered MOS transistors. The high-voltage transistors have a gate breakdown voltage above VPP. In contrast, normal MOS transistors have a gate breakdown voltage above VDD, not necessarily above VPP. The reason for the use of high-voltage transistors for all the transistors that constitute the write control unit BLCW is that VPP is used as the power supply. Consequently, the write control unit BLCW also plays the role of a level conversion circuit that converts signals having an amplitude of VDD into ones having an amplitude of VPP. While the write control unit BLCW has an output amplitude of VPP, the control signals XCont and YCont for controlling the circuit therefore have only to have an amplitude of VDD. The wiring that transmits the control signals XCont extends through the entire length of the array area AA in the row direction. The wiring that transmits the control signals YCont extends through the entire length of the array area AA in the column direction. The suppression of the amplitudes of the control signals XCont and YCont to VDD thus allows a reduction in power consumption and provides improved transmission speed.

Although its circuit diagram is omitted, the read control unit BLCR shown in FIG. 7 activates the read signals SIG1 to SIG3 in a predetermined sequence when the read signal XR supplied from the read timing signal generating circuit 16X in the corresponding control signal generating circuit 14X and the read signal YR supplied from the read timing signal generating circuit 16Y in the corresponding control signal generating circuit 14Y are activated. The latch control unit BLCLA activates latch activation signals SAP and SAN to the VDD level and VSS level, respectively, in a write operation and in a read operation.

As shown in FIG. 7, the bit line select circuit BSEL is a circuit for connecting any one of bit lines BL corresponding to the bit line control unit circuit BLC1 to BLCL concerned to the corresponding global bit line GBL. The selection is made by a bit line select address BLSADD. The bit line select address BLSADD is a signal obtained by decoding part of a row address that is supplied from outside simultaneously with an active command (ACT).

The global bit line GBL is connected to the reset write driver RESETWD, the set write driver SETWD, and the read circuit RC.

The reset write driver RESETWD is a circuit that supplies a reset pulse to the global bit line GBL, thereby supplying the reset pulse to memory cells MC through the bit line BL that is selected by the bit line select circuit BSEL. Specifically, the reset write driver RESETWD includes a constant current source CS1 and a P-channel MOS transistor Tr10 which are connected in series between the VPP power supply line and the global bit line GBL, and a P-channel MOS transistor Tr11 and N-channel MOS transistors Tr12 and Tr13 which are connected in series between the VPP power supply line and the VSS power supply line. The constant current source CS1 is a circuit that supplies a reset current IR. The gate electrode of the transistor Tr10 is connected to the drains of the transistors Tr11 and Tr12. The reset write timing pulse WRESET from the write control unit BLCW is supplied to the gate electrodes of the transistors Tr11 and Tr12. The gate electrode of the transistor Tr13 is connected to one input/output node e of the data latch circuit DL.

With such a configuration, when the one input/output node e of the data latch circuit DL is at a high level and the reset write timing pulse WRESET is activated to a high level, the transistor Tr10 turns on to supply the reset current IR to the global bit line GBL.

The set write driver SETWD is a circuit that supplies a set pulse to the global bit line GBL, thereby supplying the set pulse to memory cells MC through the bit line BL that is selected by the bit line select circuit BSEL. Specifically, the set write driver SETWD includes a constant current source CS2 and a P-channel MOS transistor Tr20 which are connected in series between the VPP power supply line and the global bit line GBL, and a P-channel MOS transistor Tr21 and N-channel MOS transistors Tr22 and Tr23 which are connected in series between the VPP power supply line and the VSS power supply line. The constant current source CS2 is a circuit that supplies a set current IS. The gate electrode of the transistor Tr20 is connected to the drains of the transistors Tr21 and Tr22. The set write timing pulse WSET from the write control unit BLCW is supplied to the gate electrodes of the transistors Tr21 and Tr22. The gate electrode of the transistor Tr23 is connected to the other input/output node f of the data latch circuit DL.

With such a configuration, when the other input/output node f of the data latch circuit DL is at a high level and the set write timing pulse WSET is activated to a high level, the transistor Tr20 turns on to supply the set current IS to the global bit line GBL.

The read circuit RC is a circuit that pre-charges the selected bit line BL through the global bit line GBL, and determines the electrical resistance of a memory cell MC based on the subsequent discharge speed. Specifically, the read circuit RC includes N-channel MOS transistors Tr30 to Tr32. The transistor Tr30 is connected between a read potential V1 and the global bit line GBL. The transistor Tr31 is connected between the global bit line GBL and the one input/output node e of the data latch circuit DL. The transistor Tr32 is connected between a reference potential VREF and the other input/output node f of the data latch circuit DL. The read signal SIG1 is supplied to the gate electrode of the transistor Tr30. The read signal SIG2 is supplied to the gate electrodes of the transistors Tr31 and Tr32 in common.

With such a configuration, the read signal SIG1 is turned to a high level to pre-charge a bit line BL before the bit line BL is discharged through a selected memory cell MC. If the memory cell MC is in a high-resistance amorphous state (reset state), the potential of the one input/output node e of the data latch circuit BL becomes higher than that of the other input/output node f. Conversely, if the selected memory cell MC is in a low-resistance crystalline state (set state), the potential of the one input/output node e of the data latch circuit DL becomes lower than that of the other input/output node f. The data read from the memory MC is thereby sensed.

As shown in FIG. 7, the reset write driver RESETWD includes an N-channel MOS transistor Tr14, whose gate electrode is connected to the drains of the transistors Tr11 and Tr12. The set write driver SETWD includes an N-channel MOS transistor Tr24, whose gate electrode is connected to the drains of the transistors Tr21 and Tr22. The read circuit RC includes an N-channel MOS transistor Tr33, whose gate electrode is supplied with the read signal SIG3. Such transistors Tr14, Tr24, and Tr33 are connected in series between the global bit line GBL and the VSS power supply line. When all the transistors Tr14, Tr24, and Tr33 are turned on, the global bit line GBL is fixed to the VSS level. The transistor Tr14 is a transistor for preventing the global bit line GBL from being connected to the VSS power supply line during a reset write. The transistor Tr24 is a transistor for preventing the global bit line GBL from being connected to the VSS power supply line during a set write.

The data latch circuit DL is a flip-flop circuit with two cross-coupled inverters. The latch activation signal SAP is used as a high-level power supply, and the latch activation signal SAN as a low-level power supply. When the latch activation signals SAP and SAN are activated to the VDD level and VSS level, respectively, the logical levels of the input/output nodes e and f are retained.

The data switch circuit DSW includes an N-channel MOS transistor Tr40 which is connected between the corresponding global I/O line GION and the one input/output node e of the data latch circuit DL, and an N-channel MOS transistor Tr41 which is connected between the corresponding global I/O line GIOT and the other input/output node f of the data latch circuit DL. The data switch signal DATASW is commonly supplied to the gate electrodes of the transistors Tr40 and Tr41. Consequently, when the data switch signal DATASW is activated to a high level, the corresponding pair of global I/O lines. GIO is connected to the pair of input/output nodes e and f of the data latch circuit DL.

Among the MOS transistors shown in FIG. 7, those having a gate electrode shown in a thick line are high-voltage transistors with a thick gate insulator, and those having a gate electrode shown in a thin line are normal transistors with a thin gate insulator. The high-voltage transistors have a gate breakdown voltage above VPP, and the normal transistors a gate breakdown voltage above VDD.

As shown in FIG. 7, the various types of signals output from the common control circuit BLCC are commonly supplied to the L bit line control unit circuits BLC1 to BLCL. As a result, the L bit line control unit circuits BLC1 to BLCL make parallel operations to transmit and receive read data and write data through the respective corresponding global I/O lines GIO.

The circuit configuration of the semiconductor device 10 according to the present embodiment has been described so far. Next, the operation of the semiconductor device 10 according to the present embodiment will be described.

FIG. 10 is a timing chart for mainly explaining the operation of the column control circuit CC when column commands are issued.

The example shown in FIG. 10 deals with a case where write commands (W) are issued in synchronization with external command clocks TC0, TC1, TC2, and TC8, and a read command (R) is issued in synchronization with external command clock TC4. A column address (aD,q) is input at the time of issuance of the write command in synchronization with TC0. This notation means that the column address selects the bit line control circuit BLC(aD,q). More specifically, the D-side bit line control circuit that is assigned to the memory cell array ARY belonging to the ath row and qth column is selected. In the same way, column addresses as shown in FIG. 10 are input at the time of issuance of the write and read commands in synchronization with the external command clocks TC1, TC2, TC4, and TC8.

When a write command or read command and a column address are input, an X column address CAX and a Y column address CAY are output in synchronization with an internal array clock which lags slightly behind the external command clock. For example, at an internal array clock T0 corresponding to the external command clock TC0, a value aD (RaD) is output as the X column address CAX, and a value q (Cq) is output as the Y column address CAY.

In response to the write commands, the write instruction signal WRITE is activated at the internal array clocks T0, T1, T2, and T8. In response to the write and read commands, the data switch signal DATASW is activated at the internal array clocks T0, T1, T2, T4, and T8.

As shown in FIG. 10, the phase signals PHASE_1 to PHASE_P generated by the write phase counter WPC are activated in succession each time the write instruction signal WRITE is activated. When, for example, the phase signal PHASE_1 is activated, the corresponding write start signal WSTART_P1, write end signal WRESETEND_P1, and write end signal WSETEND_P1 are activated in succession. As described previously, the activation timing of such signals is defined by the amounts of delay of the delay circuits DELAY2 to DELAY4. The write end signal WSETEND_P1 which is the latest to be activated is activated immediately before the internal array clock T8. This means that the write operation started at the internal array clock T0 is completed immediately before the internal array clock T8, in which case the time needed for a write operation is eight clock cycles.

In the example shown in FIG. 10, the column address (aD,q) at the time of issuance of the write command in synchronization with the external command clock TC0 and the column address (aD,s) at the time of issuance of the write command in synchronization with the external command clock TC2 have the X column addresses CAX of the same value (=aD). In the control signal generating circuit 14X(aD) corresponding to the row aD, the hit signal ADDHIT is activated in synchronization with the internal array clocks T0 and T2. The hit signal ADDHIT in synchronization with T0 is thus assigned to phase 1, and the hit signal ADDHIT in synchronization with T2 is assigned to phase 3.

In the example shown in FIG. 10, the column address (aD,q) at the time of issuance of the write command in synchronization with the external command clock TC0 and the column address (aD,q) at the time of issuance of the write command in synchronization with the external command clock TC8 have the X column addresses CAX and Y column addresses CAY of the same respective values (=aD,q). It follows that the same bit line control circuit BLC(aD,q) is activated in response to these write commands. In the present example, as mentioned previously, the time needed for a write operation is as long as eight clock cycles. The write operation corresponding to the external command clock TC0 is thus properly completed before the execution of the write operation corresponding to the external command clock TC8. The operations therefore will not interfere with each other.

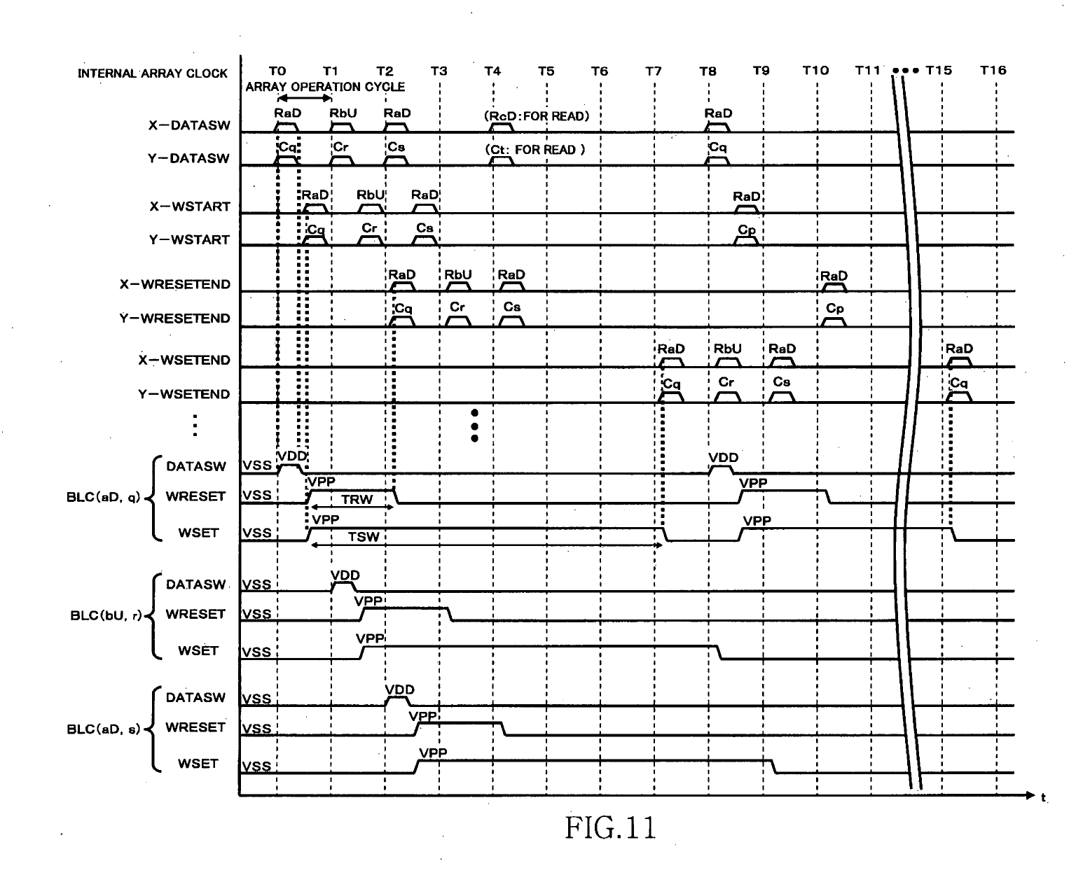

FIG. 11 is a timing chart for mainly explaining the operation of the bit line control circuits BLC when column commands are issued. The timing chart shown in FIG. 11 corresponds to the one shown in FIG. 10. That is, the input timing of the column commands and the values of the corresponding column addresses are as shown in FIG. 10.

As shown in FIG. 11, the row-direction data switch signal X-DATASW activated changes to aD, bU, aD, and aD (RaD, RbU, RaD, and RaD) in synchronization with T0, T1, T2, and T8, respectively. Similarly, the column-direction data switch signal Y-DATASW activated changes to q, r, s, and q (Cq, Cr, Cs, and Cq) in synchronization with T0, T1, T2, and T8, respectively. Incidentally, at T4 which corresponds to a read command, the read timing signal generating circuits 16X and 16Y included in the control signal generating circuit 14X in the cDth row and the control signal generating circuit 14Y in the tth column are activated to generate read signals XR and YR, respectively.

When the data switch signal X-DATASW is activated as described above, the activated write start signal X-WSTART, write end signal X-WRESETEND, and write end signal X-WSETEND also change in the foregoing order. Similarly, when the data switch signal Y-DATASW is activated as described above, the activated write start signal Y-WSTART, write end signal Y-WRESETEND, and write end signal Y-WSETEND also change in the foregoing order.

As a result, the bit line control circuit BLC(aD,q) in the aDth row and the qth column is activated in synchronization with the internal array clock T0. As shown in FIG. 11, the reset write timing pulse WRESET is activated in the reset write period TRW, and the set write timing pulse WSET is activated in the set write period TSW. Consequently, a write operation is performed on the corresponding memory cell array ARY in the ath row and the qth column. Here, whether to perform a reset operation or a set operation on the selected memory cell MC depends on the logical level of the write data. More specifically, if the corresponding global I/O line GION is at a high level (write data=0), the reset write driver RESETWD is activated (the transistor Tr10 turns on) to supply a reset pulse to the memory cell MC. On the other hand, if the corresponding global I/O line GIOT is at a high level (write data=1), the set write driver SETWD is activated (the transistor Tr20 turns on) to supply a set pulse to the memory cell MC. It should be noted that the time between the start of a write operation by the bit line control circuit BLC(aD, q) and the end of the write operation is longer than the activation period of the corresponding data switch signal X-DATASW(aD) and the activation period of the corresponding data switch signal Y-DATASW(q) irrespective of whether to perform a reset operation or a set operation.

During the bit line control circuit BLC(aD,q) is performing the write operation, the bit line control circuit BLC(bU,r) in the bUth row and the rth column is activated in synchronization with the internal array clock T1. The bit line control circuit BLC(aD,s) in the aDth row and the sth column is further activated in synchronization with the internal array clock T2. Since the bit line control circuit BLC(aD,q) activated in synchronization with the internal array clock T0 and the bit line control circuit BLC(aD,s) activated in synchronization with the internal array clock T2 belong to the same row but respective different columns, the two bit line control circuits BLC can make independent operations without interfering with each other. The reason for the possibility of such independent operations is that the data switch signals X-DATASW and the like have a pulsed waveform, and the write control unit BLCW included in each bit line control circuit BLC is provided with latch circuits (reset write timing latch circuit RESETL and set write timing latch circuit SETL). The same holds for read operations. The read control circuit BLCR included in each bit line control circuit BLC is provided with latch circuits so that a plurality of bit line control circuits BLC can perform read operations in parallel. As described above, according to the present embodiment, it is possible for a bit line control circuit BLC to start a write operation when another bit line control circuit BLC is performing a write operation. The bit line control circuits BLC that make parallel operations may belong to the same row or belong to the same column.

Subsequently, the bit line control circuit BLC(aD,q) is activated again in synchronization with the internal array clock T8. No operation interference occurs because eight clock cycles have elapsed since the internal array clock T0.

As has been described above, according to the present embodiment, any one of the plurality of bit line control circuits BLC laid out in a matrix is selectively activated by supplying the control signals XCont corresponding to each row through a plurality of lines extending in the row direction and supplying the control signals YCont corresponding to each column through a plurality of lines extending in the column direction. This eliminates the need to supply timing signals and the like to all the bit line control circuits BLC in common, allowing a reduction in the number of lines.

In addition, since the selection of the operation phase is not made on the side of the bit line control circuits BLC but on the side of the control signal generating circuits 14X and 14Y, the bit line control circuits BLC are simplified in circuit configuration. Even if the number of phases needs to be increased for accelerated external command clocks etc., the bit line control circuits BLC themselves need not be modified in circuit configuration. This can reduce the area of the chip where the bit line control circuits BLC occupy.

As described above, according to the present embodiment, the bit line control circuits BLC are controlled in operation by the logical sums of the control signals XCont which are transmitted in the row direction in the array area AA and the control signals YCont which are transmitted in the column direction in the array area AA. The control signals XCont and the control signals YCont therefore need to be in properly-matched timing. It is therefore desirable that consideration be given to the time constants that result from the capacitances and resistances of the wiring that transmits the control signals XCont and YCont. For that purpose, it is preferred that the wiring extending in the X direction, i.e., the wiring intended for the control signals XCont laid in the array area AA and the wiring from the column control circuit CC to the control signal generating circuits 14Y (such as the phase signal lines for transmitting the timing signals TMG) be formed by using the same wiring layer. Similarly, it is preferred that the wiring extending in the Y direction, i.e., the wiring intended for the control signals YCont laid in the array area AA and the wiring from the column control circuit CC to the control signal generating circuits 14X (such as the phase signal lines for transmitting the timing signals TMG) be formed by using the same wiring layer. It is also preferred that such wiring be adjusted in wiring width and wiring pitch so that the control signals XCont and YCont arrive in the respective bit line control circuits, simultaneously.

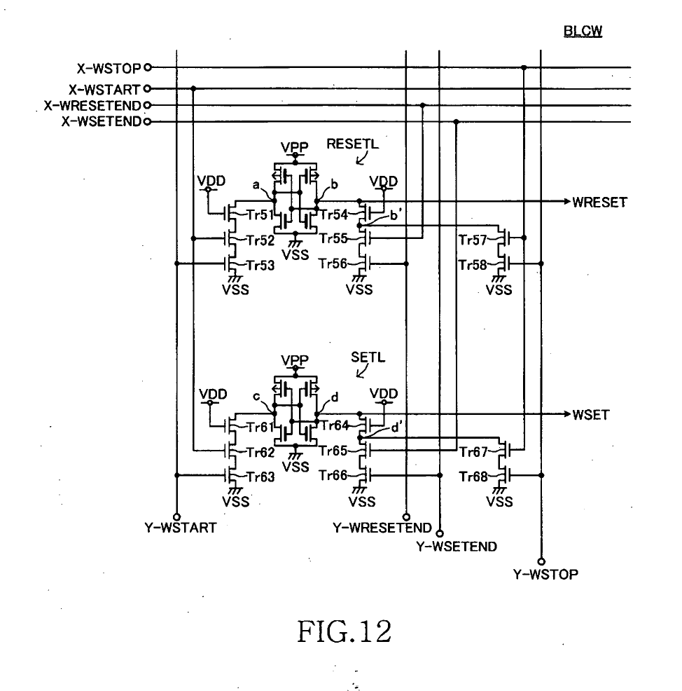

FIG. 12 is a circuit diagram of the write control unit BLCW according to a modification.

As shown in FIG. 12, in the write control unit BLOW according to the modification, N-channel MOS transistors Tr51 to Tr53 are connected in series between the one input node a of the reset write timing latch circuit RESETL and the VSS power supply line. N-channel MOS transistors Tr54 to Tr56 are connected in series between the other input node b and the VSS power supply line. Similarly, N-channel MOS transistors Tr61 to Tr63 are connected in series between the one input node c of the set write timing latch circuit SETL and the VSS power supply line. N-channel MOS transistors Tr64 to Tr66 are connected in series between the other input node d and the VSS power supply line.

The corresponding write start signal X-WSTART is supplied to the gate electrodes of the transistors Tr52 and Tr62. The corresponding write start signal Y-WSTART is supplied to the gate electrodes of the transistors Tr53 and Tr63. The corresponding write end signal X-WRESETEND is supplied to the gate electrode of the transistor Tr55. The corresponding write end signal Y-WRESETEND is supplied to the gate electrode of the transistor Tr56. The corresponding write end signal X-WSETEND is supplied to the gate electrode of the transistor Tr65. The corresponding write end signal Y-WSETEND is supplied to the gate electrode of the transistor Tr66.

The gate electrodes of the transistors Tr51, Tr54, Tr61, and Tr64 are fixed to VDD.

Among the MOS transistors shown in FIG. 12, those having a gate electrode shown in a thick line are high-voltage transistors with a thick gate insulator, and those having gate electrode shown in a thin line are normal transistors with a thin gate insulator. The high-voltage transistors have a gate breakdown voltage above VPP, and the normal transistors a gate breakdown voltage above VDD. In the write control unit BLCW according to the modification, the transistors Tr51 to Tr56 and Tr61 to Tr66 are normal transistors, not high-voltage transistors. Consequently, although the number of transistors is greater than in the write control unit BLCW shown in FIG. 9, the occupied area decreases instead. This point will be described below.

Semiconductor devices for use in mobile apparatuses such as a cellular phone need extremely low power consumption in a standby state. To achieve this, it is essential to reduce MOS transistors' off-leak currents. Increasing the threshold voltages of MOS transistors is effective in reducing the off-leak currents of the MOS transistors.

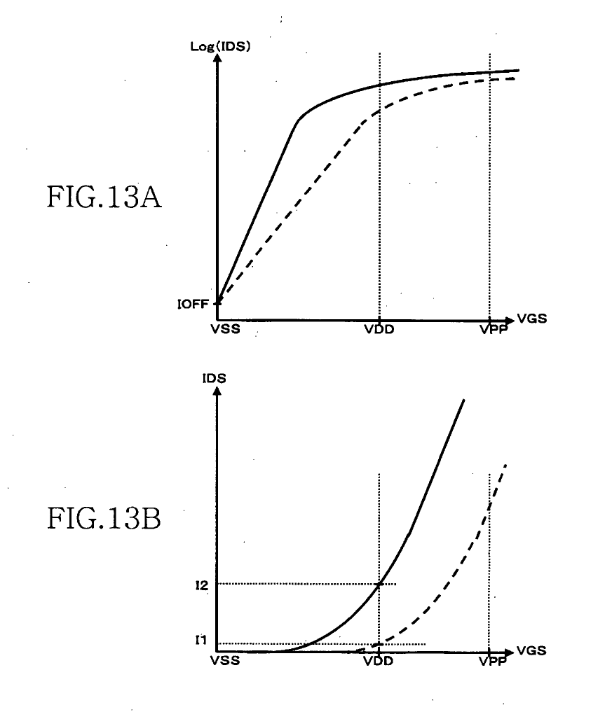

FIGS. 13A and 13B are graphs showing the relationship between the gate-source voltage and the drain current. FIG. 13A is a graph showing the drain current on a log scale. FIG. 13B is a graph showing the drain current on a normal scale. In FIGS. 13A and 13B, the solid line shows the characteristic of a normal transistor with a thin gate insulator. The broken line shows the characteristic of a high-voltage transistor with a thick gate insulator.

The characteristic shown in FIG. 13A is referred to as a “subthreshold characteristic.” The gradient of the straight portion where the gate-source voltage is low is referred to as an “S factor”. As shown in FIG. 13A, the normal transistor has a higher S factor (the gradient is steeper), and the high-voltage transistor has a lower S factor (the gradient is gentler). Given threshold voltages designed for the same off-leak current, the normal transistor has an on current (IDS) higher than that of the high-voltage transistor.

When designing a semiconductor device, the threshold voltages are adjusted so that the total sum of the off-leak currents of the transistors on the entire chip falls within an allowable range. With semiconductor devices intended for mobile apparatuses in particular, the off-leak currents need to be made considerably small. If the high-voltage transistors have a gate-source voltage of the VDD level, the drain current (IDS) becomes extremely low. To secure a sufficient drain current, the high-voltage transistors then need to be designed with a large channel width. In other words, to secure the same drain current, each single high-voltage transistor occupies an area considerably larger than a normal transistor does. The larger channel width also increases the gate capacitance accordingly, with an increase in the operating current.

In contrast, the write control unit BLCW shown in FIG. 12 includes the transistors Tr51, T54, Tr61, and Tr64 whose gate electrodes are fixed to the VDD power supply line. This makes it possible to constitute all the transistors Tr51 to Tr56 and Tr61 to Tr66 of normal transistors. More specifically, the drain voltages of the transistors T52, Tr53, Tr55, Tr56, Tr62, Tr63, Tr65, and Tr66 are suppressed to a maximum of VDD−Vt (the threshold voltage of the transistor Tr51 and the like), which eliminates the need to use high-voltage transistors. The gate-drain voltages of the transistors Tr51, Tr54, Tr61, and Tr64 are suppressed to VPP−VDD, which eliminates the need for high-voltage transistors. Consequently, it is possible to suppress the off-leak currents and reduce the area occupied by the write control unit BLCW. Since the gate capacitances are reduced as well, it is even possible to reduce the operating power consumption.

The write control unit BLCW shown in FIG. 12 includes additional N-channel MOS transistors. Tr57, Tr58, Tr67, and Tr68. The transistors Tr57 and Tr58 are connected in series between the node b′ and the VSS power supply line. The transistors Tr67 and Tr68 are connected in series between the node d′ and the VSS power supply line. A write stop signal X-WSTOP is commonly supplied to the gate electrodes of the transistors Tr57 and Tr67. A write stop signal Y-WSTOP is commonly supplied to the gate electrodes of the transistors Tr58 and Tr68.

The write stop signals X-WSTOP and Y-WSTOP are signals to be activated when interrupting a write operation of the corresponding bit line control circuit BLC. For instance, in the example shown in FIG. 11, write operations using the same bit line control circuit BLC are instructed in synchronization with the internal array clocks T0 and T8. In such a case, the write operation corresponding to the internal array clock T0 can be properly completed before the execution of the write operation corresponding to the internal array clock T8. On the other hand, if a write operation using the same bit line control circuit BLC is instructed at or before the internal array clock T7, the new write operation needs to be started before the write operation corresponding to the internal array clock T0 is properly completed. In such a case, the write stop signals X-WSTOP and Y-WSTOP are activated to forcefully deactivate the reset write timing latch circuit RESETL and the set write timing latch circuit SETL so that the new write operation can be started from the beginning. In this case, the write operation corresponding to the internal array clock T0 is not properly completed, whereas the write data need not be properly written anyway since the write data is to be overwritten by the new write operation.

The write stop signals X-WSTOP and Y-WSTOP can also be used to deactivate the reset write timing latch circuit RESETL and the set write timing latch circuit SETL upon power-on. Typical semiconductor devices have a circuit for sensing power-on, called a power-on reset circuit. The write stop signals X-WSTOP in all the rows and the write stop signals Y-WSTOP in all the columns may be activated to a high level in response to the output of the power-on reset circuit.

Next, description will be given of read operations.

If read operations have a read time longer than the array operation cycle, a control such as operating a plurality of phases in parallel is also needed in read operations. The same phase control as with write operations can be used in such a case.

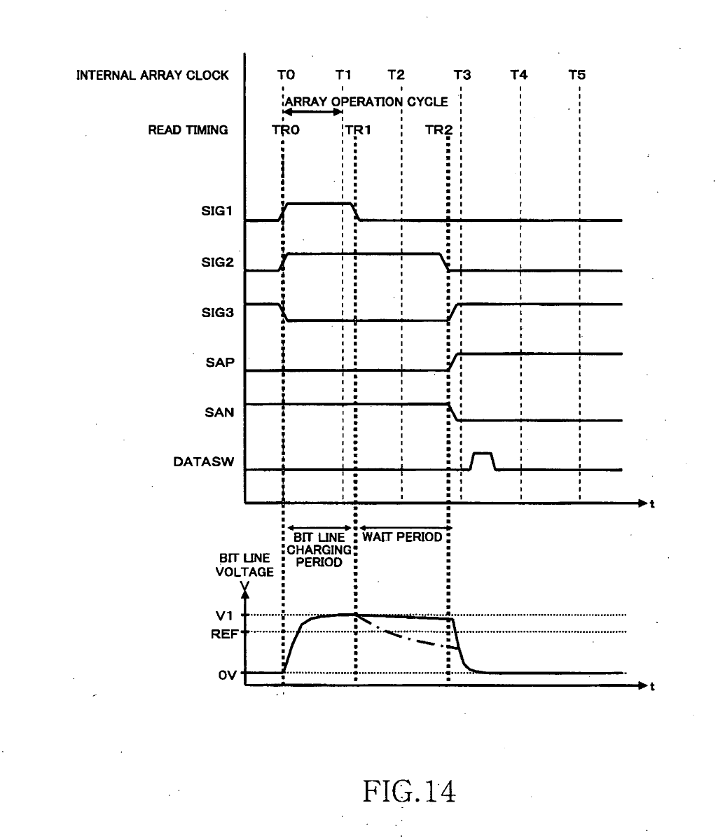

FIG. 14 is a timing chart when a method of reading read data from a memory cell MC in response to a read command is used.

In the method, the read signals SIG1 to SIG3 and the latch activation signals SAP and SAN shall have respective waveforms shown in FIG. 14. In FIG. 14, the period of read timing TR0 to TR1 is a bit line charging period where the transistors Tr30 and Tr31 included in the read circuit of FIG. 7 are on. In the period, the selected bit line BL is charged to the voltage V1 through the global bit line GBL. In the period of read timing TR1 to TR2 shown in FIG. 14 is a wait period where the transistor Tr31 is on. In the period, the potential of the charged bit line BL falls, being discharged through the selected memory cell MC. If the phase change element PC of the selected memory cell MC is in a high-resistance amorphous state (reset state), the bit line BL falls gently in potential. If the phase change element PC is in a low-resistance crystalline state (set state), the bit line BL drops rapidly in potential.

At read timing TR2, the latch activation signals SAP and SAN are activated to the VDD level and VSS level, respectively, whereby the result of sensing of the read circuit is latched into the data latch circuit. Subsequently, the data switch signal DATASW is activated to output the latched read data to the global I/O lines GIO. The bit line control circuit BLC thereby completes the read operation.

In the example shown in FIG. 14, the read operation started at the internal array clock T0 is completed immediately before T4. In such an example, read operations therefore need to be controlled in four phases or more. The phase control on read operations may be performed by the same method as with write operations. More specifically, the common control circuit BLCC in the bit line control circuit BLC is provided with latch circuits for retaining the activation periods of the read signals SIG1 to SIG3 and the latch activation signals SAP and SAN, respectively. The latch circuits are inverted at timing TR0, TR1, and TR2. The three timings TR0, TR1, and TR2 can be obtained by AND gate circuits receiving the signals that are laid in the row direction and column direction of the array area. In read operations, the data switch DATASW can be controlled by the circuits shown in FIGS. 5, 6, and 8. As an example of the phase control circuit for a read operation, a circuit having the same configuration as that of the circuit pertaining to the write control of the phase timing circuit PTC shown in FIG. 5 is provided. The output signals of such a circuit can be supplied to the read timing signal generating circuit 16X and 16Y in the control signal generating circuits 14X and 14Y as timing signals TMG.

As has been described above, according to the present embodiment, it is possible with a simple circuit, i.e., a circuit of small layout area to control a semiconductor device in which the write time and read time on the memory cells MC are longer than the array control cycle and a plurality of write and read timing or phases are needed within a single array area AA. Since the number of phases can be increased without increasing the circuit scale of the array area AA or the number of lines, it is possible to reduce the layout area of the array area regardless of the number of phases.

It is apparent that the present invention is not limited to the above embodiments, but may be modified and changed without departing from the scope and spirit of the invention.

For example, the control signals YCont to be simultaneously activated need not be those of any one of the K columns. The control signals YCont of a plurality of columns may be simultaneously activated. The reason is that the global I/O lines GIO are independent of each other column by column. As an application example, a DDR3-SDRAM sequence operation can include the simultaneous input of data as much as a plurality of addresses with different addresses Y0 to Y2 for a single write command. With the addresses Y0 to Y2 as respective column addresses, the pieces of data may be written to the corresponding memory cell arrays ARY through the respective corresponding global I/O lines GIO. As another application example, the number of bits of data to be simultaneously input/output (word configuration) can be switched, for example, from eight bits to 16 bits by switching the number of control signals YCont to be simultaneously activated.

In addition, while not specifically claimed in the claim section, the applicant reserves the right to include in the claim section of the application at any appropriate time the following devices:

A1. A semiconductor device comprising:

a plurality of memory cell arrays that are arranged in a matrix in a row direction and a column direction, each of the memory cell arrays including a plurality of memory cells;

a plurality of control circuits each assigned to an associated one of the plurality of memory cell arrays, each of the control circuits including a data latch circuit that latches write data or read data;

a plurality of first control signal lines that extend in the row direction and parallel to each other in the column direction;

a plurality of second control signal lines that extend in the column direction and parallel to each other in the row direction;

a plurality of global I/O lines that extend in the column direction and parallel to each other in the row direction;

a first control signal generating circuit that activates any one of the plurality of first control signal lines; and

a second control signal generating circuit that activates any one of the plurality of second control signal lines, wherein

each of the plurality of first control signal lines is connected to a plurality of control circuits that belong to a same row,

each of the plurality of second control signal lines is connected to a plurality of control circuits that belong to a same column,

each of the plurality of global I/O lines is connected to a plurality of control circuits that belong to the same column,

among the plurality of control circuits, a control circuit that is connected to activated first and second control signal lines takes write data supplied through a corresponding global I/O line into the data latch circuit or supplies read data taken into the data latch circuit to the corresponding global I/O line,

each of the plurality of memory cell arrays includes a plurality of bit lines that are connected to respective corresponding memory cells,

each of the data latch circuits is commonly assigned to the corresponding plurality of bit lines, and

each of the plurality of control circuits includes a bit line select circuit that supplies the write data latched in the data latch circuit to any one of the plurality of bit lines included in the corresponding memory cell array, or supplies read data read from any one of the plurality of bit lines included in the corresponding memory cell array to the data latch circuit.

A2. The semiconductor device as A1, further comprising:

a plurality of first write start signal lines that extend in the row direction and parallel to each other in the column direction; and

a plurality of second write start signal lines that extend in the column direction and parallel to each other in the row direction, wherein

each of the plurality of first write start signal lines is connected to a plurality of control circuits that belong to the same row,

each of the plurality of second write start signal lines is connected to a plurality of control circuits that belong to the same column, and

among the plurality of control circuits, a control circuit that is connected to activated first and second write start signal lines starts supplying the write data latched in the data latch circuit to the bit line.

A3. The semiconductor device as A2, further comprising:

a plurality of first write end signal lines that extend in the row direction and parallel to each other in the column direction; and

a plurality of second write end signal lines that extend in the column direction and parallel to each other in the row direction, wherein

each of the plurality of first write end signal lines is connected to a plurality of control circuits that belong to the same row,

each of the plurality of second write end signal lines is connected to a plurality of control circuits that belong to the same column, and

among the plurality of control circuits, a control circuit that is connected to activated first and second write end signal lines ends supplying the write data latched in the data latch circuit to the bit line.

A4. The semiconductor device as A3, wherein first time between activation of predetermined first and second write start signal lines and activation of corresponding first and second write end signal lines is longer than second time that is minimum time between the activation of the predetermined first and second write start signal lines and activation of first and second write start signal lines different from the predetermined first and second write start signal lines.

A5. The semiconductor device as A4, wherein

the first control signal generating circuit activates any one of the plurality of first control signal lines, any one of the plurality of first write start signal lines, and any one of the plurality of first write end signal lines in synchronization with any of a plurality of phase signals, and

the second control signal generating circuit activates any one of the plurality of second control signal lines, any one of the plurality of second write start signal lines, and any one of the plurality of second write end signal lines in synchronization with any of the plurality of phase signals.

A6. The semiconductor device as A5, wherein the number of the plurality of phase signals is greater than the first time divided by the second time.

A7. The semiconductor device as A5, wherein the plurality of phase signals are not supplied to the plurality of control circuits but to a first phase signal line that extends in the column direction within the first control signal generating circuit and a second phase signal line that extends in the row direction within the second control signal generating circuit.

A8. The semiconductor device as A7, wherein

the plurality of phase signals are generated by a phase timing circuit that is arranged in an area where an extension of the first control signal generating circuit in the column direction and an extension of the second control signal generating circuit in the row direction intersect each other,

the plurality of first control signal lines, the plurality of first write start signal lines, the plurality of first write end signal lines, and the second phase signal line are formed in an identical wiring layer, and

the plurality of second control signal lines, the plurality of second write start signal lines, the plurality of second write end signal lines, and the first phase signal line are formed in an identical wiring layer.

A9. The semiconductor device as A4, wherein activation periods of the first and second control signal lines, the first and second write start signal lines, and the first and second write end signal lines are shorter than the second time.

What is claimed is:

1. A semiconductor device comprising:
first and second memory cell arrays each including a plurality of memory cells;
first and second control circuits each controlling the first and second memory cell arrays, respectively;
a first control signal line connected to the first and second control circuits in common to transmit a first control signal;
a second control signal line connected to the first control circuit to transmit a second control signal; and
a third control signal line connected to the second control circuit to transmit a third control signal, wherein
the first control circuit performs an operation control on the first memory cell array when the first and second control signals are activated,
the second control circuit performs an operation control on the second memory cell array when the first and third control signals are activated,
time between when the first control circuit starts the operation control on the first memory cell array and when the first control circuit ends the operation control is longer than an activation period of the first and second control signals, and
time between when the second control circuit starts the operation control on the second memory cell array and when the second control circuit ends the operation control is longer than an activation period of the first and third control signals.

2. The semiconductor device as claimed in claim 1, further comprising:
third and fourth memory cell arrays each including a plurality of memory cells;
third and fourth control circuits each controlling the third and fourth memory cell arrays, respectively; and
a fourth control signal line connected to the third and fourth control circuits in common to transmit a fourth control signal, wherein
the third control circuit performs an operation control on the third memory cell array when the second and fourth control signals are activated,
the fourth control circuit performs an operation control on the fourth memory cell array when the third and fourth control signals are activated,
time between when the third control circuit starts the operation control on the third memory cell array and when the third control circuit ends the operation control is longer than an activation period of the second and fourth control signals, and
time between when the fourth control circuit starts the operation control on the fourth memory cell array and when the fourth control circuit ends the operation control is longer than an activation period of the third and fourth control signals.

3. The semiconductor device as claimed in claim 2, further comprising:
a first global I/O line connected to the first control circuit; and
a second global I/O line connected to the second control circuit, wherein
the first control circuit includes:
a first data latch circuit that retains write data to be written to anyone of the memory cells included in the first memory cell array or read data read from any one of the memory cells included in the first memory cell array;
a first data switch circuit that connects the first global I/O line to, the first data latch circuit; and
a first data switch control unit that turns on the first data switch circuit in response to activation of the first and second control signals, and
the second control circuit includes:
a second data latch circuit that retains write data to be written to any one of the memory cells included in the second memory cell array or read data read from any one of the memory cells included in the second memory cell array;
a second data switch circuit that connects the second global I/O line to the second data latch circuit; and
a second data switch control unit that turns on the second data switch circuit in response to activation of the first and third control signals.

4. The semiconductor device as claimed in claim 3, wherein
the third control circuit includes:
a third data latch circuit that retains write data to be written to any one of the memory cells included in the third memory cell array or read data read from any one of the memory cells included in the third memory cell array;
a third data switch circuit that connects the first global I/O line to the third data latch circuit; and
a third data switch control unit that turns on the third data switch circuit in response to activation of the second and fourth control signals, and
the fourth control circuit includes:
a fourth data latch circuit that retains write data to be written to any one of the memory cells included in the fourth memory cell array or read data read from any one of the memory cells included in the fourth memory cell array;
a fourth data switch circuit that connects the second global I/O line to the fourth data latch circuit; and
a fourth data switch control unit that turns on the fourth data switch circuit in response to activation of the third and fourth control signals.

5. The semiconductor device as claimed in claim 3, further comprising:
a first write start signal line connected to the first and second control circuits in common to transmit a first write start signal;
a second write start signal line connected to the first control circuit to transmit a second write start signal;
a third write start signal line connected to the second control circuit to transmit a third write start signal;
a first write end signal line connected to the first and second control circuits in common to transmit a first write end signal;
a second write end signal line connected to the first control circuit to transmit a second write end signal; and
a third write end signal line connected to the second control circuit to transmit a third write end signal, wherein
the first control circuit starts writing the write data retained in the first data latch circuit in response to activation of the first and second write start signals,
the first control circuit ends writing the write data retained in the first data latch circuit in response to activation of the first and second write end signals,
the second control circuit starts writing the write data retained in the second data latch circuit in response to activation of the first and third write start signals, and
the second control circuit ends writing the write data retained in the second data latch circuit in response to activation of the first and third write end signals.

6. The semiconductor device as claimed in claim 5, further comprising:
a fourth write end signal line connected to the first and second control circuits in common to transmit a fourth write end signal;
a fifth write end signal line connected to the first control circuit to transmit a fifth write end signal; and
a sixth write end signal line connected to the second control circuit to transmit a sixth write end signal, wherein
the first control circuit ends writing the write data retained in the first data latch circuit in response to the activation of the, first and second write end signals if the write data retained in the first data latch circuit is at a first logical level,
the first control circuit ends writing the write data retained in the first data latch circuit in response to activation of the fourth and fifth write end signals if the write data retained in the first data latch circuit is at a second logical level,
the second control circuit ends writing the write data retained in the second data latch circuit in response to the activation of the first and third write end signals if the write data retained in the second data latch circuit is at the first logical level, and
the second control circuit ends writing the write data retained in the second data latch circuit in response to activation of the fourth and sixth write end signals if the write data retained in the second data latch circuit is at the second logical level.

7. The semiconductor device as claimed in claim 5, wherein
each of the first and second memory cell arrays includes a plurality of bit lines that are connected to respective corresponding memory cells,
the first control circuit further includes a first bit line select circuit that connects the first global I/O line to any one of the plurality of bit lines included in the first memory cell array, and
the second control circuit further includes a second bit line select circuit that connects the second global I/O line to any one of the plurality of bit lines included in the second memory cell array.

8. The semiconductor device as claimed in claim 7, wherein
the first control circuit further includes a write driver that supplies a write pulse to a bit line selected by the first bit line select circuit in response to the activation of the first and second write start signals, and
the write pulse has a voltage amplitude greater than that of write data supplied through the first global I/O line.

9. The semiconductor device as claimed in claim 8, wherein the first control circuit further includes:
a write timing latch circuit that is connected between first and second power supply lines, sets a write timing pulse to be supplied to the write driver to a potential of the first power supply line when in an active state, and sets the write timing pulse to a potential of the second power supply line when in an inactive state;
first and second transistors that are connected in series between one input node of the write timing latch circuit and the second power supply line, each of the first and second transistors has a control electrode to which the first and second write start signals are supplied, respectively; and
third and fourth transistors that are connected in series between other input node of the write timing latch circuit and the second power supply line, each of the third and fourth transistors has a control electrode to which the first and second write end signals are supplied, respectively, and
wherein the write timing latch circuit enters the active state when the one input node is connected to the second power supply line, and enters the inactive state when the other input node is connected to the second power supply line.

10. The semiconductor device as claimed in claim 9, wherein the first to fourth transistors are MOS transistors and have a gate breakdown voltage higher than a voltage between the first and second power supply lines.

11. The semiconductor device as claimed in claim 9, wherein the first control circuit further includes:
a fifth transistor that is connected between a series circuit including the first and second transistors and the one input node of the write timing latch circuit; and
a sixth transistor that is connected between a series circuit including the third and fourth transistors and the other input node of the write timing latch circuit, and wherein
the first to sixth transistors are MOS transistors,
the gates of the fifth and sixth transistors are connected to a third power supply line to which a potential between the potential of the first power supply line and that of the second power supply line is supplied, and
the first to fourth transistors have a gate insulating film thinner than that of MOS transistors that constitute the write timing latch circuit.

12. The semiconductor device as claimed in claim 1, wherein time for changing the plurality of memory cells from a first memory state to a second memory state is different from time for changing the plurality of memory cells from the second memory state to the first memory state.

13. The semiconductor device as claimed in claim 1, wherein each of the plurality of memory cells includes a nonvolatile memory element using phase change material.

14. A semiconductor device comprising:
a plurality of memory cell arrays arranged in a matrix, each of the memory cell arrays including a plurality of memory cells;
a plurality of control circuits provided correspondingly to the memory cell arrays and arranged in a matrix;
a plurality of first lines each extending in a row direction of the matrix, and each transferring a first signal in common to corresponding ones of the first control circuits arranged in line in the row direction; and
a plurality of second lines each extending in a column direction of the matrix, and each transferring a corresponding second signal in common to corresponding ones of the first control circuits arranged in line in the column direction;
each of the control circuits accessing an associated one of the memory cell arrays upon receiving the first signal from an associated one of the first lines simultaneously with the second signal from an associated one of the second lines.

15. The semiconductor device as claimed in claim 14, wherein the first and second signals have first and second pulse widths, respectively, and each of the first and second pulse widths smaller than a period for which each of the first control circuits accesses the associated one of the memory cell arrays.

16. The semiconductor device as claimed in claim 14, wherein the first and second signals are generated in response to a read command and the accessing is a read operation.

17. The semiconductor device as claimed in claim 14, wherein the first and second signals are generated in response to a write command and the accessing is a write operation.

18. The semiconductor device as claimed in claim 14, wherein the memory cells include phase change memories, respectively.

19. The semiconductor device as claimed in claim 14, wherein each of the control circuits is not allowed to access the associated one of the memory cell arrays upon receiving the first signal from the associated one of the first lines at a first timing with the second signal from the associated one of the second lines at a second timing different from the first timing.

20. A semiconductor device comprising:
a memory cell array that includes a plurality of memory cells and a plurality of bit lines connected to respective corresponding memory cells;
a bit line select circuit that connects any one of the plurality of bit lines to a global bit line;
a reset write driver and a set write driver that are connected to the global bit line;
a data latch circuit that latches write data supplied through a global I/O line;
a reset write timing latch circuit that defines an activation period of the reset write driver; and
a set write timing latch circuit that defines an activation period of the set write driver, wherein
the data latch circuit latches the write data supplied through the global I/O line in response to simultaneous activation of first and second control signals,
the reset write timing latch circuit enters an active state in response to simultaneous activation of first and second write start signals and enters an inactive state in response to simultaneous activation of first and second write end signals,
the set write timing latch circuit enters an active state in response to the simultaneous activation of the first and second write start signals and enters an inactive state in response to simultaneous activation of third and fourth write end signals,
the reset write driver supplies a reset pulse to the global bit line in response to the reset write timing latch circuit entering the active state if a first logical level is latched in the data latch circuit, and
the set write driver supplies a set pulse to the global bit line in response to the set write timing latch circuit entering the active state if a second logical level is latched in the data latch circuit.

21. The semiconductor device as claimed in claim 20, further comprising a read circuit that is connected to the global bit line, wherein
in a read operation, read data read by the read circuit is output to the global I/O line.

22. The semiconductor device as claimed in claim 20, wherein
the first control signal, the first write start signal, and the first and third write end signals are all supplied through corresponding signal lines that extends in the row direction, and
the second control signal, the second write start signal, and the second and fourth write end signals are all supplied through corresponding signal lines that extends in the column direction.
